(19) United States
(12) Patent Application Publication
(10) Pub. No.: US 2015/0076449 A1
(43) Pub. Date: Mar. 19, 2015

(54) SEMICONDUCTOR DEVICE AND MANUFACTURING METHOD THEREOF

(71) Applicant: FUJITSU LIMITED, Kawasaki-shi (JP)

(72) Inventor: Atsushi Yamada, Isehara (JP)

(73) Assignee: FUJITSU LIMITED, Kawasaki (JP)

(21) Appl. No.: 14/450,550

(22) Filed: Aug. 4, 2014

(30) Foreign Application Priority Data
Sep. 19, 2013 (JP) 2013-194413

(51) Int. Cl. H01L 29/778; H01L 29/66; H01L 29/205; H01L 29/15; H01L 29/20

(52) U.S. Cl. CPC H01L 29/7785; H01L 29/151; H01L 29/2003; H01L 29/205; H01L 29/66431
USPC 257/20; 438/172

(57) ABSTRACT

A semiconductor device includes a superlattice buffer layer formed on a substrate. An upper buffer layer is formed on the superlattice buffer layer. A first semiconductor layer is formed by a nitride semiconductor on the upper busier layer. A second semiconductor layer is formed by a nitride semiconductor on the first semiconductor layer. A gate electrode, a source electrode and a drain electrode are formed on the second semiconductor layer. The superlattice buffer layer is formed by cyclically laminating nitride semiconductor films having different composition. The upper buffer layer is formed by a nitride semiconductor material having a band gap wider than a band gap of the first semiconductor layer and doped with an impurity element that causes a depth of an acceptor level to be greater than or equal to 0.5 eV.

### CROSS-REFERENCE TO RELATED APPLICATIONS

This application is based upon and claims the benefit of priority of the prior Japanese Patent Application No. 2013-194413, filed on Sep. 19, 2013, the entire contents of which are incorporated herein by reference.

### FIELD

The embodiments discussed herein are directed to a semiconductor device and a manufacturing method of a semiconductor device.

### BACKGROUND

A nitride semiconductor has features such as a high saturation electron speed, a wide hand gap, etc. Thus, it is considered to apply the nitride semiconductor to semiconductor devices having a high withstand voltage and a high output. For example, the bad gap of GaN, which is a nitride semiconductor, is 3.4 eV, which is higher than the band gap of Si (1.1 eV) and the band gap of GaAs (1.4 eV). Thus, GaN has a high breakdown electric field strength. Accordingly, the nitride semiconductor such as GaN or the like is extremely hopeful as a material to fabricate a power supply semiconductor device providing a high-voltage operation and a high-output.

As a semiconductor device using a nitride semiconductor, there are many reports with respect to a filed effect transistor, particularly, a high electron mobility transistor (HEMT). For example, from among GaN-HEMTs, an HEMT made of AlGaN/GaN attracts attention wherein GaN is used as an electron transit layer and AlGaN is used as an electron supply layer. In the HEMT made of AlGaN/GaN, a strain is generated in AlGaN due to a difference in lattice constant between GaN and AlGaN. Thereby, a highly concentrated two-dimensional electron gas (2DEG) can be obtained due to a piezoelectric polarization caused by such a strain and an intrinsic polarization difference. Thus, the AlGaN/GaN-HEMT is hopeful as a high-efficiency switch device and a high withstand voltage power device for electric vehicle.

In order to reduce a manufacturing cost of such a semiconductor device using a nitride semiconductor, a study for crystal growth on an Si substrate has been conducted. However, it is difficult to increase a withstand voltage because the Si substrate has a low insulation property. Patent Document 1 discloses a method of reducing a leak current to improve a withstand, voltage by forming a thick superlattice buffer layer of a strained-layer superlattice (SLS) structure on an Si substrate.

The following patent documents discloses a background art.

Patent Document 1: Japanese Patent No. 5179635

Patent Document 2: Japanese Laid-Open Patent Application No. 2012-160608

FIG. 1 illustrates a semiconductor device using a nitride semiconductor in which a superlattice buffer layer is formed. As illustrated in FIG. 1, the semiconductor device has a structure in which a nitride semiconductor layer is laminated on a silicon substrate 910. Specifically, a nuclear formation layer 911, a buffer layer 912, a superlattice buffer layer 913, an electron transit layer 931 and an electron supply layer 932 are sequentially laminated on the silicon substrate 910. A gate electrode 941, a source electrode 942 and a drain electrode 943 are formed on the electron supply layer 932.

The nuclear formation layer 911 is formed by AlN. The buffer layer 912 is formed by AlGaN. The superlattice buffer layer 813 is formed by alternately laminating an AlN film and a GaN film for a predetermined number of periods or cycles. The electron transit layer 931 is formed by i-GaN, and the electron supply layer 932 is formed, by n-AlGaN. Thereby, a two-dimensional electron gas (2DEG) 931a is created in the electron transit layer 931 near the interface between the electron transit layer 931 and the electron supply layer 932.

FIG. 2 is an energy band diagram of the superlattice buffer layer 913, the electron transit layer 931 and the electron supply layer 932 in the semiconductor device illustrated in FIG. 1. As illustrated in FIG. 2, AlN has a wide band gap and electron holes are pooled at the interface between the AlN film of the superlattice buffer layer 913 and the electron transit layer 931, thereby creating a two-dimensional hole gas (2DEG).

If 2DEG is created at the interface between the superlattice duffer layer 913 and the electron transit layer 931 in the semiconductor device illustrated in FIG. 1, a leak current flowing in a transverse direction, which is parallel to the silicon substrate 910, is increased.

Additionally, in order to improve a withstand voltage, there is a method of forming an AlGaN layer 920 into which Mg is doped between the superlattice buffer layer 913 and the electron transit layer 931 as illustrated in FIG. 3. In such a case, by doping Mg into AlGaN, a shallow acceptor level is formed, which creates holes in the AlGaN layer 920 doped with Mg. Accordingly, it is difficult to prevent generation of a leak current flowing in a transverse direction substantially parallel to the silicon substrate 910. Because Mg is easily diffusible, diffuses to the electron transit layer 931 formed by GaN in a film deposition process or a heat treatment process. Thus, a leak current flowing in a transverse direction is further increased. Additionally, because a band is raised, an on-resistance is increased.

Thus, it is desired to provide a semiconductor device having a superlattice buffer layer and a nitride semiconductor formed on a silicon substrate in which a leak current is reduced.

### SUMMARY

There is provided according to an aspect of the embodiments, a semiconductor device including: a superlattice buffer layer formed on a substrate; an upper buffer layer formed on the superlattice buffer layer; a first semiconductor layer formed by a nitride semiconductor on the upper buffer layer; a second semiconductor layer formed by a nitride semiconductor on the first semiconductor layer; and a gate electrode, a source electrode and a drain electrode formed on the second semiconductor layer, wherein the superlattice buffer layer is formed by cyclically laminating nitride semiconductor films having different compositions, and the upper buffer layer is formed by a nitride semiconductor material having a band gap wider than a band gap of the first semiconductor layer and doped with an impurity element that causes a depth of an acceptor level to be greater than or equal to 0.5 eV.

There is provided according to another aspect of the embodiments a manufacturing method of a semiconductor device, including: forming a superlattice buffer laver on a substrate; forming an upper buffer layer on the superlattice buffer layer; forming a first semiconductor layer by a nitride semiconductor on the upper buffer layer. A second semiconductor layer is formed by a nitride semiconductor on said first semiconductor layer. A gate electrode, a source electrode and a drain electrode are formed on said second semiconductor layer. The superlattice buffer layer is formed by alternately and cyclically laminating nitride semiconductor films having different compositions, and the upper buffer layer is formed by a nitride semiconductor material having a band gap wider than a band gap of the first semiconductor layer and doped with an impurity element that causes a depth of an acceptor level to be greater than or equal to 0.5 eV.

The object and advantages of the embodiments will be realized said attained by means of the elements and combinations particularly pointed out in the appended claims.

It is to be understood that both the foregoing general description and the following detailed description are exemplary explanatory only and are not restrictive of the invention as claimed.

### BRIEF DESCRIPTION OF DRAWINGS

FIG. 1 is a cross-sectional view of a semiconductor device in which a superlattice buffer layer is formed;

FIG. 2 is an energy band diagram of a portion of the semiconductor device illustrated in FIG. 1;

FIG. 3 is a cross-sectional view of a semiconductor device in which a superlattice buffer layer is formed;

FIG. 4 is an energy band diagram of a portion of the semiconductor device illustrated in FIG. 3;

FIG. 5 is a cross-sectional view of a semiconductor device according to a first embodiment;

FIG. 6 is a energy band diagram of a portion of the semiconductor device according to the first embodiment;

FIGS. 7A through 7D are cross-sectional views for explaining a manufacturing process of the semiconductor device according to the first embodiment;

FIGS. 8A and 8B are illustrations for explaining an upper buffer layer of the semiconductor device according to the first embodiment;

FIG. 9 is a cross-sectional view of a semiconductor device according to a second embodiment;

FIG. 10 is an energy band diagram of a portion of the semiconductor device according to the second embodiment;

FIGS. 11A and 11B are illustrations for explaining an upper buffer layer of the semiconductor device according to the second embodiment;

FIG. 12 is a cross-sectional view of another semiconductor device according to the second embodiment;

FIG. 13 is a cross-sectional view of a semiconductor device according to a third embodiment;

FIG. 14 is an energy band diagram of a portion of the semiconductor device according to the third embodiment;

FIGS. 15A and 15B are illustrations for explaining art upper buffer layer of the semiconductor device according to the third embodiment;

FIG. 16 is a cross-sectional view of another semiconductor device according to the third embodiment;

FIG. 17 is a cross-sectional view of a semiconductor device according to a fourth embodiment;

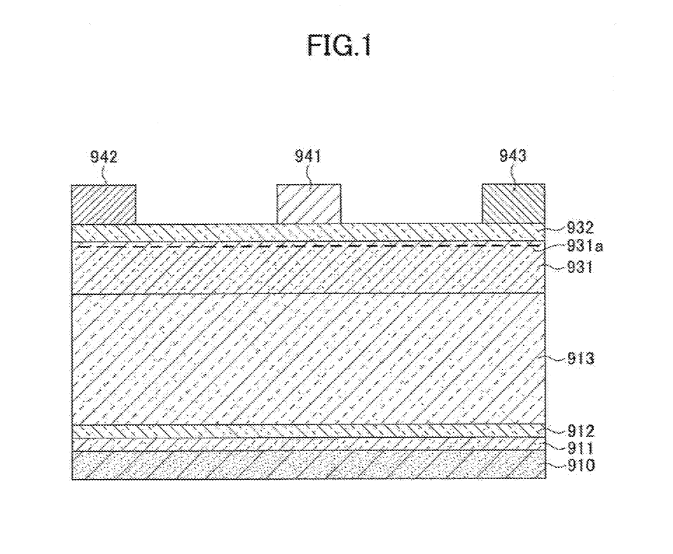

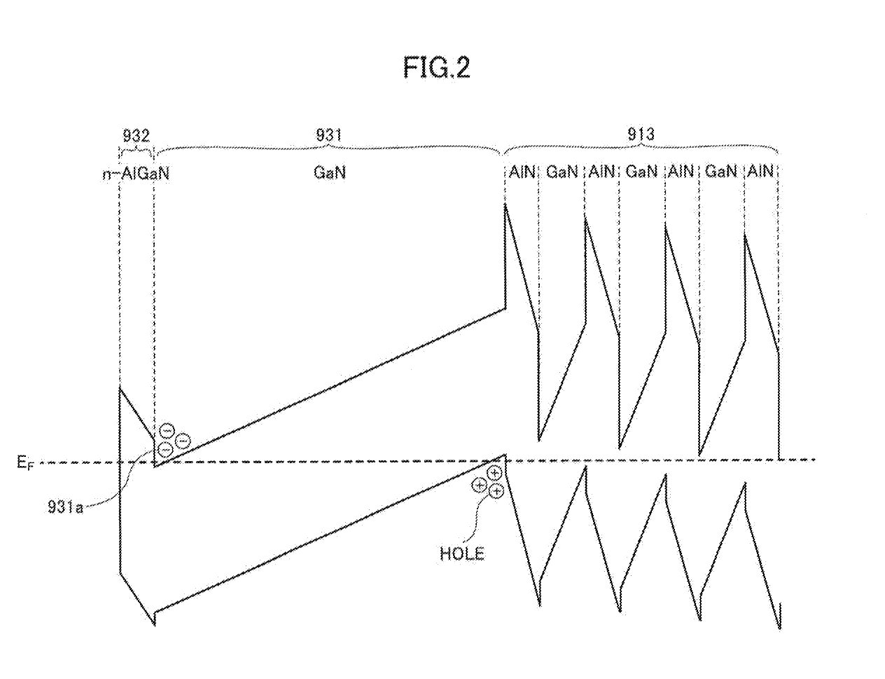

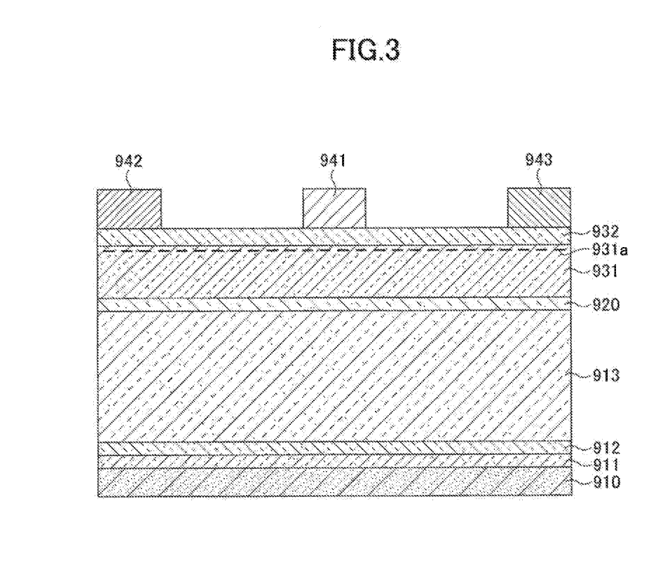

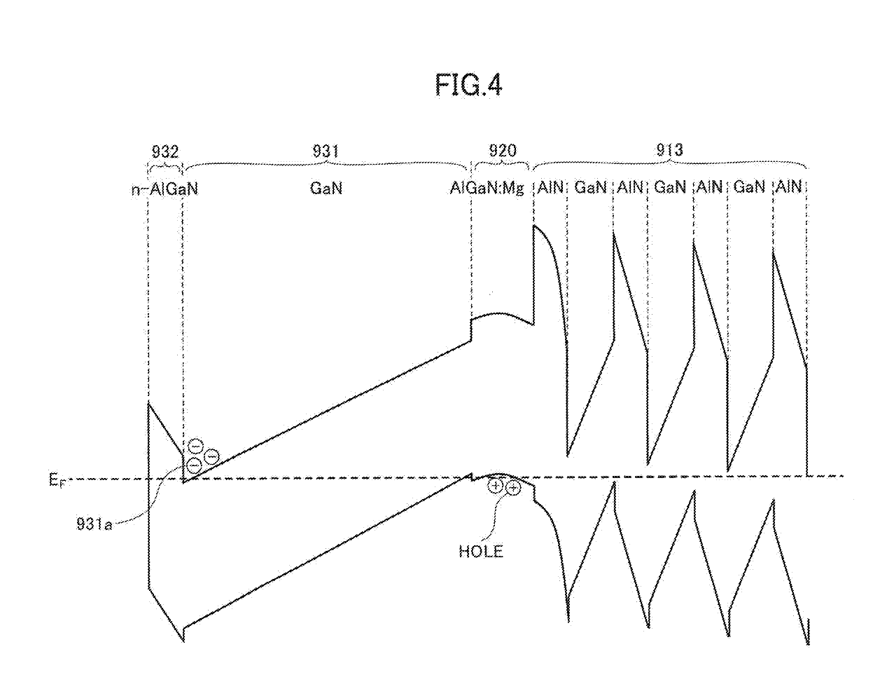

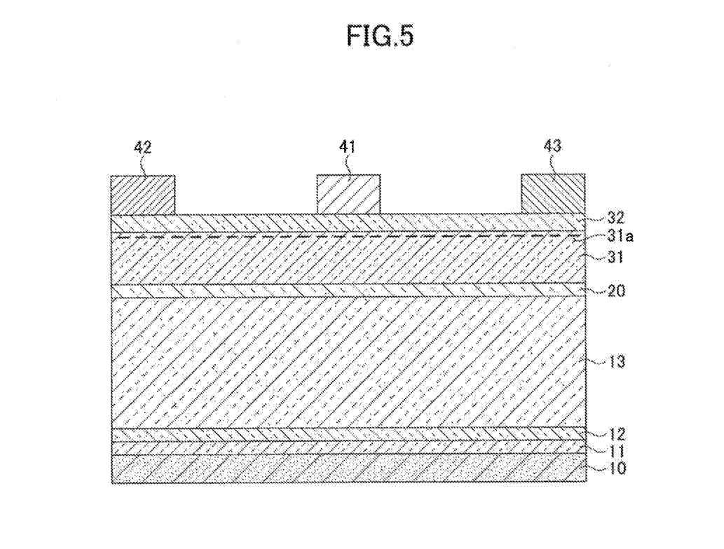

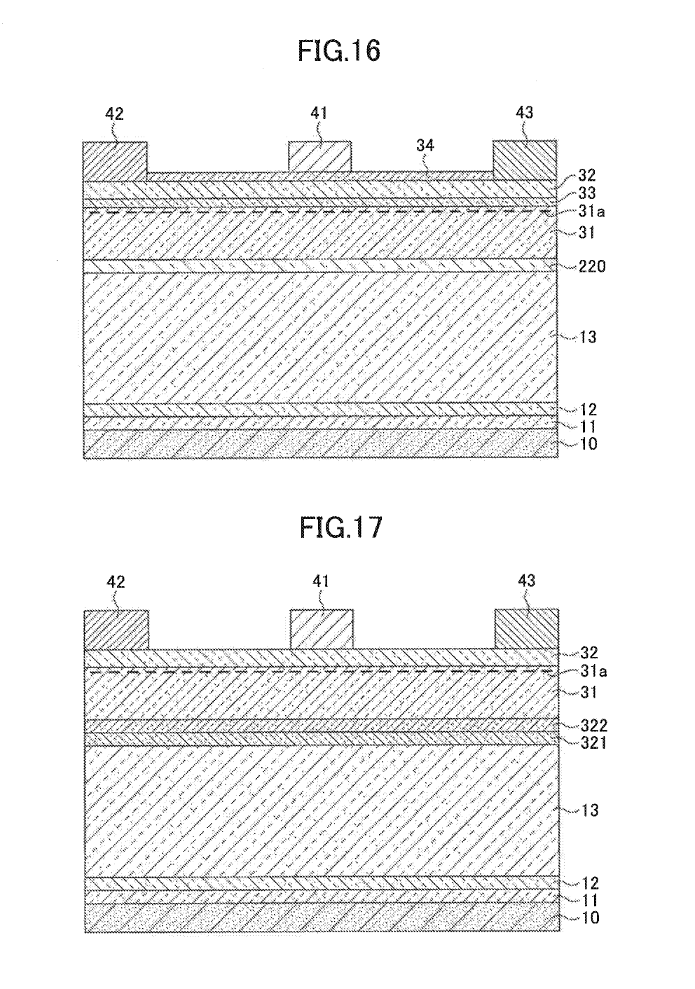

FIG. 16 is an energy band diagram of a portion of the semiconductor device according to the fourth embodiment;

FIGS. 19A and 19B are illustrations for explaining art upper barter layer of the semiconductor device according to the fourth embodiment;

FIG. 20 is a cross-sectional view of another semiconductor device according to the fourth embodiment;

FIG. 21 is a cross-sectional view of a semiconductor device according to a fifth embodiment;

FIG. 22 is an energy band diagram of a portion of the semiconductor device according to the fifth embodiment;

FIGS. 23A and 23B are illustrations for explaining an upper buffer layer of the semiconductor device according to the fifth embodiment;

FIG. 24 is a cross-sectional view of another semiconductor device according to the fifth embodiment;

FIG. 25 is a cross-sectional view of a supper lattice buffer layer according to a sixth embodiment;

FIG. 26 is a graph indicating a relationship between a film thickness of an AlN layer and a warp value of a silicon substrate deformed in a downward convex shape;

FIG. 27 is a graph indicating a relationship between a film thickness of an AlN layer and a withstand voltage;

FIG. 28 is an energy band diagram of a superlattice buffer layer having an AlN layer having a different film thickness;

FIG. 29 is an energy band diagram of a superlattice buffer layer having an AlN layer having a different film thickness;

FIG. 30 is a graph indicating a relationship between a C concentration of an AlN layer and a warp value of a silicon substrate deformed in a downward convex shape;

FIG. 31 is a graph indicating a relationship between an Fe concentration of an AlN layer and a warp value of a silicon substrate deformed in a downward convex shape;

FIGS. 32A through 32D are cross-sectional views for explaining a manufacturing process of the semiconductor device according to the sixth embodiment

FIG. 33 is a plan view of an interior of a discrete-packaged semiconductor device according to a seventh embodiment;

FIG. 34 is a circuit diagram of a power supply device according to the seventh embodiment; and

FIG. 35 is a circuit diagram of a high-power amplifier according to the seventh embodiment.

### DESCRIPTION OF EMBODIMENT(S)

A description will now be given of embodiments with reference to the drawings. In the drawings, the same parts are given the same reference number, and descriptions thereof will be omitted.

### First Embodiment

(Semiconductor Device)

A description will be given of a semiconductor device according to a first embodiment. The semiconductor device according to the first, embodiment includes a silicon substrate 10 and a nuclear formation layer 11, an lower buffer layer 12, a superlattice buffer layer 13, an upper buffer layer 20, an electron transit layer 31 and an electron supply 1 layer 32 sequentially laminated on the silicon substrate in that order. A gate electrode, a source electrode 42 and a drain electrode 43 are formed on the electron supply layer 32.

The nuclear formation layer 11 is formed by AlN. The lower buffer layer 12 is formed by AlGaN. The superlattice buffer layer 13 is formed by alternately laminating an AlN film and a GaN film for a predetermined number of cycles. The electron transit layer 31 is formed by i-GaN. The electron supply layer 32 is formed by n-AlGaN. Thereby, in the electron transit layer 31, a 2DEG 31a is created near the interface between the electron transit layer 31 and the electron supply layer 32. In the semiconductor device according to the present embodiment, a substrate formed of SiC, sapphire, etc., may be used instead of the silicon substrate 10, which is formed of silicon. Additionally, in the present embodiment, the electron transit layer 31 may be referred to as a first semiconductor layer and the electron supply layer 32 may be referred to as a second semiconductor layer.

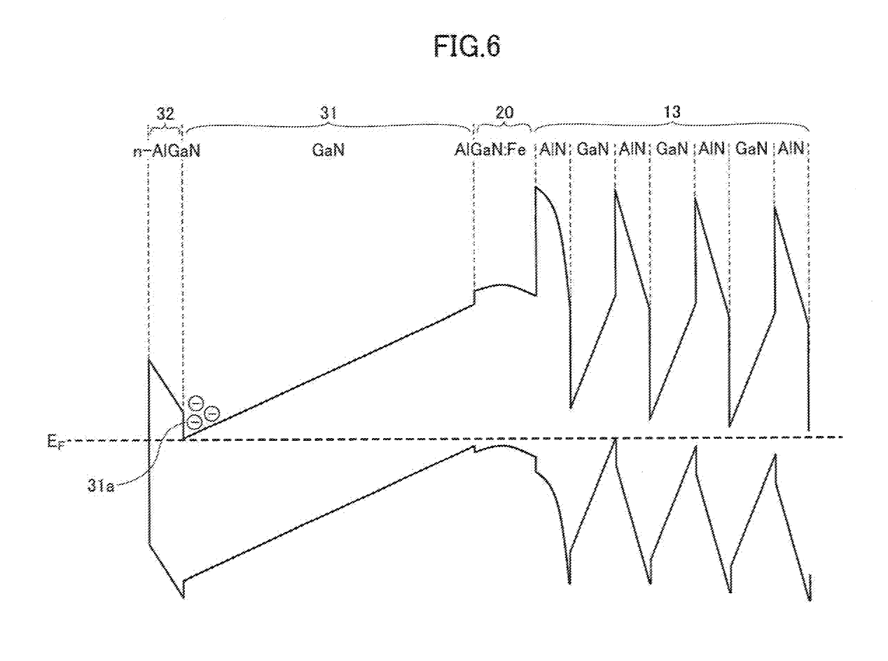

In the present embodiment, the upper buffer layer 20 is formed by AlGaN doped with Fe as an impurity element at a concentration of 5×10¹⁸ cm⁻³. By doping Fe into AlGaN, a deep acceptor level is formed as illustrated in FIG. 6. Thereby, an intrinsic polarization offset amount due to the AlN film on an outermost surface of the superlattice buffer layer 13 is increased, and a band gap becomes wide, which suppresses generation of 2DEG. It should be noted that the upper buffer layer 20 may be formed by a nitride semiconductor having a wider band grip than the nitride semiconductor forming the electron transit layer 31 and doped with an impurity element such as Fe or the like. Specifically, the upper buffer layer 20 may be a layer formed by one of GaN, AlN and InN or a nixed crystal of two or more materials selected from a group consisting of GaN, AlN and InN and doped with an impurity element such as Fe or the like.

As mentioned above, the upper buffer layer formed by AlGaN doped with Fe has a deep acceptor level, an activation rate is low and electron holes are hardly generated. Accordingly, an increase in a leak current in a transverse direction parallel to the silicon substrate 10 can be suppressed. Further, if Fe doped in the upper buffer layer 20 diffuses during a neat treatment process or a film deposition process, an activation rate is low and electron holes are hardly generated. Thereby, an increase in a leak current flowing in a transverse direction is suppressed, and an increase in an on-resistance can also be suppressed in the electron transit layer 31.

The following table 1 indicates a relationship between an impurity element doped into the upper buffer layer 20 and an acceptor level. In order to suppress generation of holes in the vicinity of the interface between the super lattice buffer layer 13 and the upper buffer layer 20, as for an impurity element doped into the upper buffer layer 20 is preferably an element which caused a depth of an acceptor level to be greater than or equal to 0.5 eV. Thus, from this point of view and based, on the table 1, one of Be, C, Fe, Cd, Li, etc., is preferably used as an impurity element to be doped. It should be noted that Mg and Zn cause an acceptor level to be smaller than 0.5 eV, which is a shallow acceptor level. Thus, Mg and Zn are not preferably used as an impurity element because there may be a case where holes are generated in the vicinity of the superlattice buffer layer 13 and the upper buffer layer 20.

TABLE 1

| Impurity Element | Acceptor Level (eV) |
|---|---|
| Mg | 0.14-0.21 |
| Zn | 0.21-0.34 |
| Be | 0.70 |
| C | 0.89 |
| Fe | 0.72 |
| Cd | 0.51 |
| Li | 0.75 |

(Manufacturing Method of Semiconductor Device)

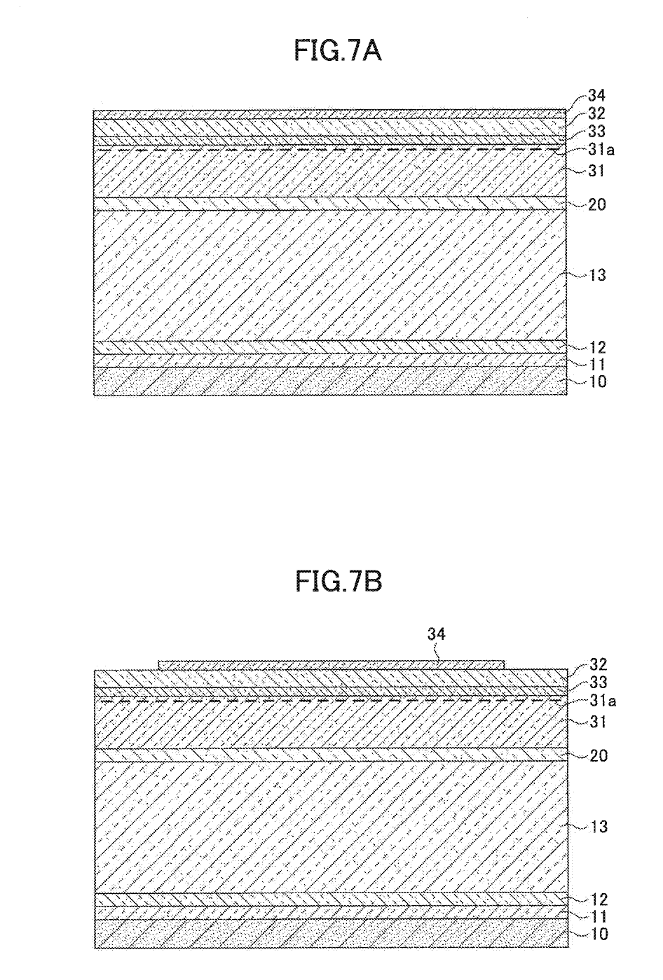

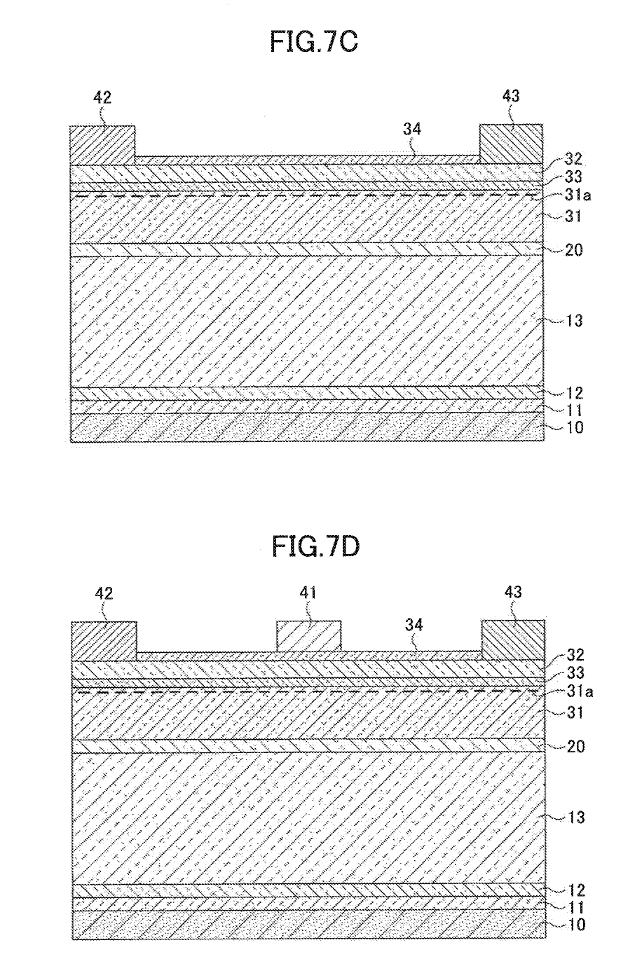

A description will be given, with reference to FIGS. 7A through 7D, of a manufacturing method of the semiconductor device according to the present embodiment. The semiconductor device according to the present embodiment may be provided with a spacer layer 33 formed by a nitride semiconductor between the electron transit layer 31 and the electron supply layer 32, and a cap layer 34 formed by a nitride semiconductor device on the electron supply layer 32. In the present embodiment, the spacer layer 33 may be referred to as a third semiconductor layer, and the cap layer 34 may be referred to as a fourth semiconductor layer.

First, as illustrated in FIG. 7A, nitride semiconductor layers are formed on the silicon substrate 10 by epitaxial growth according to a metal organic vapor phase epitaxy (MOVPE). It should be noted that when forming a nitride semiconductor layer on the silicon substrate 10, epitaxial growth according to molecular beam epitaxy (MBE) may be used.

Specifically, the nuclear formation layer 11, the lower buffer layer 12, the superlattice buffer layer 13, the upper buffer layer 20, the electron transit layer 31, the spacer layer 33, the electron supply layer 32 and the cap layer 34 are sequentially formed on the silicon substrate 10 by MOVPE. When forming those layers, trimethyl aluminum (TMA) is used as an Al source gas, trimethyl gallium (TMG) is used as a Ga source gas, and ammonium (NH₃) is uses as an N source gas. Additionally, when doping Fe as an impurity element into the upper buffer layer 20, ferrocene (Cp2Fe) is used, and when doping Si serving as an n-type impurity element monosilane (SiH₄) is used. A growth pressure when forming a nitride semiconductor layer by MOVPE is 5 kPa to 100 kPa. A substrate temperature when growing the nitride semiconductor is 900° C. to 1200° C.

The nuclear formation layer 11 is formed by AlN by supplying TMA and NH₃ as source gases. The lower buffer layer 12 is formed by Al_{0.2}Ga_{0.8}N having a film thickness of about 50 nm formed, by TMG, TMA and NH₃ as source gases. The superlattice buffer layer 12 is formed by alternately laminating an AlN film having a film thickness of about 2 nm and a GaN film having a film thickness of about 20 nm for 100 cycles, when forming the superlattice layer 13, TMG and NH₃ and TMA and NH₃ are alternately supplied. It should be noted that when forming the superlattice buffer layer 13, Fe as an impurity element can be doped at a concentration of about 5×10¹⁸ cm⁻³.

The upper buffer layer 20 is formed by Al_{0.1}Ga_{0.9}N having a film thickness of about 100 nm by supplying TMG and NH₃ as source gases. The upper buffer layer is doped with Fe as an impurity element at a concentration of about 5×10¹⁸ cm⁻³. Fe doped into the upper buffer layer 20 can be doped by supplying a predetermined amount of Cp2Fe when forming the upper buffer layer 20.

The electron transit layer 31 is formed by GaN having a film thickness of about 2 μm by supplying TMG and NH₃ as source gases. The spacer layer 33 is formed by Al_{0.2}Ga_{0.8}N having a film thickness of about 5 nm by supplying TMG, TMA, NH₃ and NH₃ as source gases. The electron supply layer 32 is formed by n-AlGaN by supplying TMG, TMA, NH₃ and SiH₄ as source gases. That is, Al_{0.2}Ga_{0.8}N having a film thickness of about 30 nm is formed and doped with Si as an impurity element at a concentration of about 5×10¹⁹ cm⁻³. The cap layer 34 is formed by n-GaN by supplying TMG, NH₃ and SiH₄ as source gases. That is, GaN having a film thickness of about 10 nm is formed and doped with Si as an impurity element, at a concentration of about 5×10¹⁸ cm⁻³.

The superlattice buffer layer 13 may be a layer other than the layer formed by laminating AlN (2 nm)/GaN (20 nm) as mentioned above. For example, the superlattice buffer layer may be a layer formed by laminating Al_{0.9}Ga_{0.1}N (10 nm)/Al_{0.1}Ga_{0.9}N (20 nm) or AlN (2 nm)/Al_{0.8}In_{0.2}N (20 nm). In the present embodiment, if an outermost surface of the superlattice buffer layer 12 is AlₓIn_{y}Ga_{(1-x-y)}N, x may be smaller than 0.5 (x>0.5) and a film thickness may be smaller than or equal to 20 nm. Additionally, a number of cycles in the superlattice buffer layer 13 is preferably 20 cycles or more, and more preferably, 50 cycles or more. The cycle may be nonuniform, and may be divided into cyclic structures having different cycles with an. intermediate layer interposed therebetween.

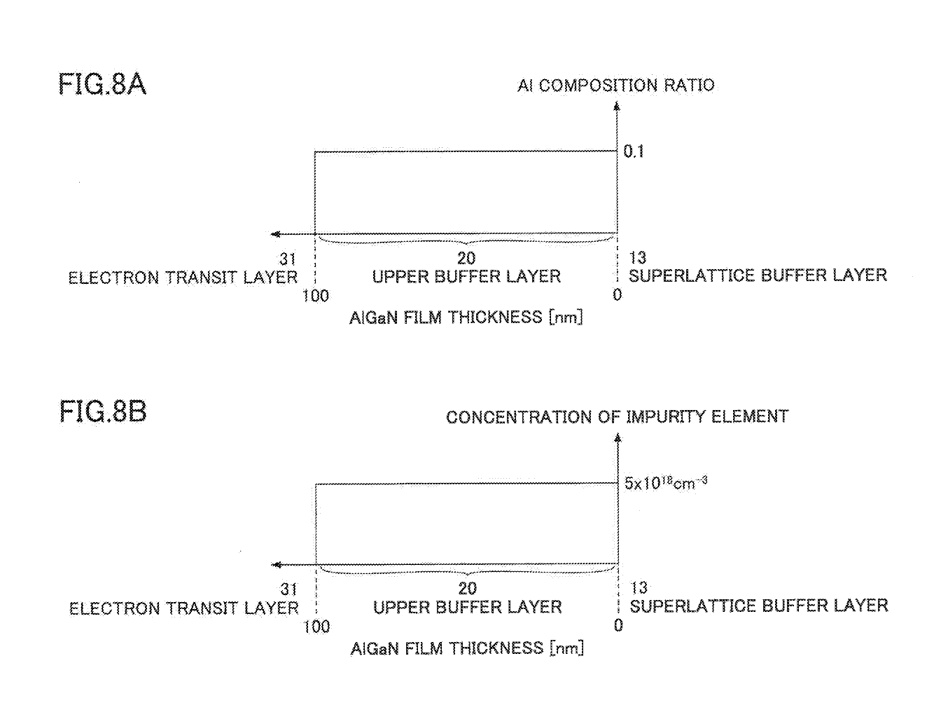

In the present embodiment, as illustrated in FIGS. 8A and 8B, the upper buffer layer 20 is formed so that an Al composition ratio is uniform without depending on a film thickness and a concentration of Fe the like serving as a doped impurity element is uniform without depending on the film thickness. Specifically, if the upper buffer layer 20 is formed by Al_{z}Ga_{1-z}N, z is preferably greater than 0 and smaller than 1.0 (0<z<1.0), and, more preferably, greater than 0 and smaller than or equal to 0.5 (0<z≦0.5). Additionally, a concentration of an impurity element such as Fe or the like coped into the upper buffer layer 20 is preferably greater than or equal to 1×10¹⁷ cm⁻³ and smaller than or equal to 1×10²⁰ cm⁻³. It should be noted that FIG. 8A illustrates a distribution of an Al composition ratio in the upper buffer layer 20. FIG. 8B illustrates a distribution of a concentration of an impurity element in the upper buffer layer 20.

Thereafter, a photoresist is applied onto the cap layer 34, and a resist pattern (not illustrated in the figure) having an opening at a portion where an element separation area is formed is formed by performing exposure and development by an exposure apparatus. Thereafter, the element separation area (not illustrated in the figure) is formed by performing dry-etching using a chlorine gas or performing ion implantation of ion such as Ar in the opening of the resist pattern. Thereafter, the resist pattern is removed by an organic solvent or the like.

Then, as illustrated in FIG. 7B, portions of the cap layer 34 in areas where the source electrode 42 and the drain electrode 43 are formed are removed. Specifically, a photoresist is applied onto the cap layer 34, and a resist pattern (not illustrated in the figure) having openings at portions where the source electrode 42 and the drain electrode 43 are to be formed is formed by performing exposure and development by an exposure apparatus. Thereafter, the portions of the cap layer 34 in the openings of the resist pattern are removed by performing dry-etching using a chlorine gas so as to cause the electron supply layer 32 to be exposed. Thereafter, the resist pattern is removed by an organic solvent or the like. Thereby, the portions of the cap layer 34 are removed in the areas where the source electrode 42 and the drain electrode 43 are formed, and the portions of the electron supply layer 32 are exposed.

Then, as illustrated in FIG. 7C, the source electrode 42 and the drain electrode 43 are formed on the electron supply layer 32. Specifically, a photoresist is applied onto the cap layer 34 and the electron supply layer 32, and a resist pattern (not illustrated in the figure) having openings in areas where the source electrode 42 and the drain electrode are to be formed is formed by performing exposure and development by an exposure apparatus. Thereafter, a metal lamination film made of Ta/Al for forming the source electrode 42 and the drain electrode 43 is formed on the electron supply layer 32 and the resist pattern. The metal lamination film is a lamination film in which Ta having a film thickness of about 20 nm is laminated on A having a film thickness of about 200 nm. The metal lamination film is formed by vacuum vapor deposition. Thereafter the metal lamination film formed on the resist pattern is removed together with the resist patter by lift-off by immersing the metal lamination film into an organic solvent. Thereby, the source electrode 42 and the drain electrode 43 are formed by remaining portions of the metal lamination film. Thereafter, an ohmic contact is established by performing a heat treatment at a temperature of 400° C. to 1000° C., for example, at 550° C. in a nitrogen atmosphere.

Then, as illustrated in FIG. 7D, the gate electrode 41 is formed on the cap layer 34. Specifically, a photoresist is applied onto the cap layer 34, the source electrode 42 and the drain electrode 43, and a resist pattern (not illustrated in the figure) having an opening in an area where the gate electrode 41 is to be formed is formed by performing exposure and development by an exposure apparatus. Thereafter, a metal lamination film made of Ni/Au for forming the gate electrode 41 is formed on the cap layer 34 and the resist pattern. The metal lamination film is a film in which Au having a film thickness of about 400 nm is laminated on Ni having a film thickness of about 30 nm. The metal lamination film is formed by a vacuum vapor deposition. Thereafter, the metal lamination film formed on the resist pattern is removed together with resist pattern by lift off by immersing the metal lamination film into an organic solvent. Thereby, the gate electrode 41 is formed by a remaining portion of the metal lamination film.

According to the above-mentioned processes, the semiconductor device according to the present embodiment is manufactured. It should be noted that the structure of each of the above-mentioned gate electrode 41, source electrode 42 and drain electrode 43 is more an example, and other multiple metal lamination films may be formed or a single layer metal film may be formed. Additionally, the gate electrode 41, source electrode 42 and drain electrode 43 may be formed by a method other than lift off. If an ohmic contact can be obtained in the source electrode 42 and the drain electrode 43 after film deposition, there is no need to perform heat treatment. Additionally, after forming the gate electrode 41, heat treatment may be performed if necessary.

Although the above-mentioned semiconductor device has a Schottky-type gate structure, the semiconductor device according to the present embodiment may be a semiconductor device having a MIS-type gated electrode structure having a gate insulation film. Additionally, the semiconductor device according to the present embodiment may be a semiconductor device having a structure in which a gate recess is formed by removing a nitride semiconductor layer directly under a gate electrode and the gate electrode is formed in the gate recess.

If the impurity element doped into the upper buffer layer 20 is C, the upper buffer layer 20 may be formed by adjusting a film deposition condition of MOVPE without supplying a gas to dope the impurity element. For example, the upper buffer layer 20 may be formed at a low substrate temperature. Specifically, the upper buffer layer 20 may be grown by MOVPE under a film deposition condition in which a substrate temperature is lower than or equal to 1050° C. and a pressure in the chamber is lower than or equal to 20 kPa. By causing a growth under such a condition, C component contained in a source gas is taken into the film, which results in automatic doping of C

### Second Embodiment

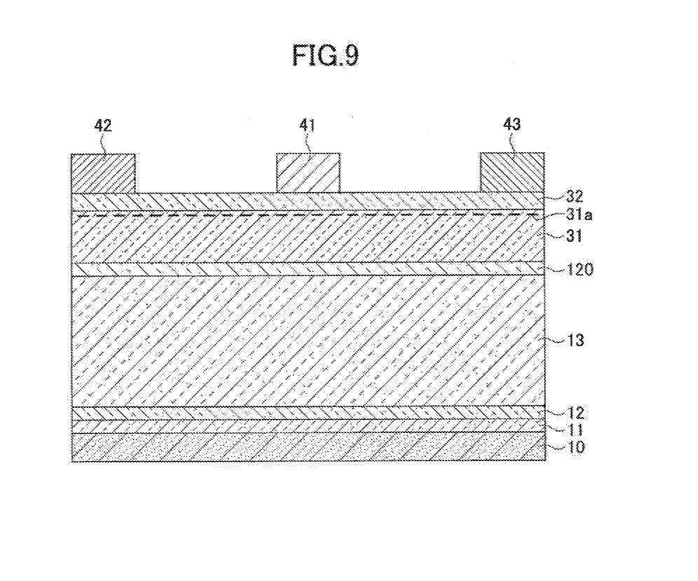

A description will be given below of a semiconductor device according to a second embodiment. As illustrated in FIG. 9, the semiconductor device according to the second embodiment includes a silicon substrate 10 and a nuclear formation layer 11, a lower buffer layer 12, a superlattice buffer layer 13, an upper buffer layer 120, an electron transit layer 31 and an electron supply layer 32 sequentially laminated on the silicon substrate 10 in that order. A gate electrode 41, a source electrode 42 and a drain electrode 43 are formed on the electron supply layer 32.

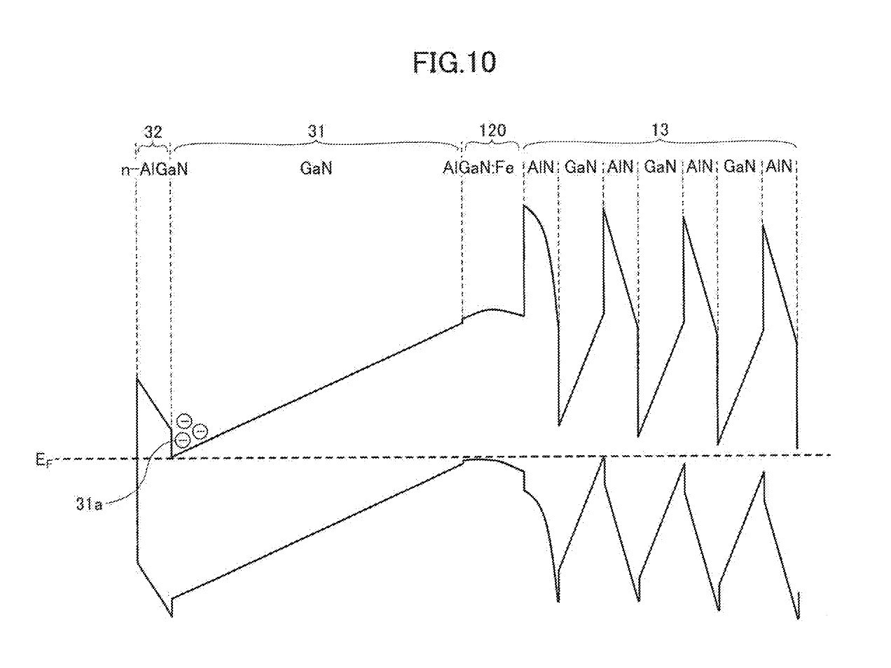

The nuclear formation layer 11 is formed by AlN. The lower buffer layer 12 is formed by AlGaN. The superlattice buffer layer 13 is formed, by alternately laminating an AlN film and a GaN film for a predetermined number of cycles. The electron transit layer 31 is formed by i-GaN. The electron supply layer 32 is formed by n-AlGaN. Thereby, in the electron transit layer 31, a 2DEG 31a is created near the interface between the electron transit layer 31 and the electron supply layer 32. FIG. 10 is an energy band diagram in the supper lattice buffer layer 13, the upper buffer layer 120, the electron transit layer 31 and the electron supply layer 32.

In the present embodiment, the upper buffer layer 120 is formed by AlGaN doped with Fe as an impurity element. Thereby, generation of holes is suppressed in the vicinity of the interface between the superlattice buffer layer 13 and the upper buffer layer 120.

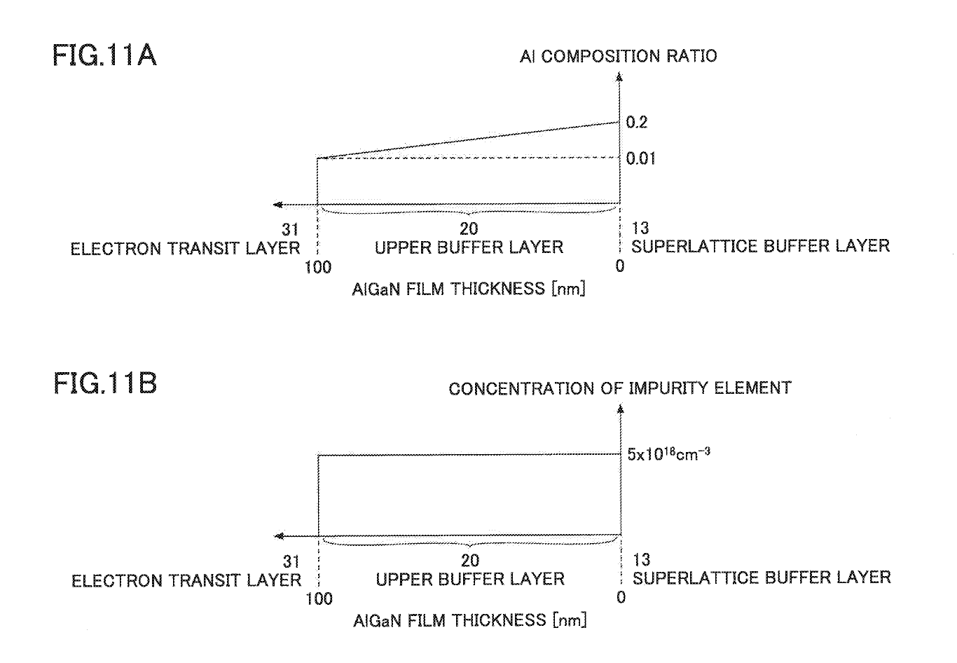

In the present embodiment, as illustrated in FIGS. 11A and 11B, the upper buffer layer 120 is formed in a composition gradient manner so that an Al composition ratio gradually decreases from a vicinity of the interface between the upper buffer layer 120 and the superlattice buffer layer 13 toward a vicinity of the interface between the upper buffer layer 120 and the electron transit layer 31. Specifically, the upper buffer layer 120 is formed in an Al composition gradient manner so that a composition of the upper buffer layer 120 near the interface between the upper buffer layer 120 and the superlattice buffer layer 13 is Al_{0.2}Ga_{0.8}N and a composition of the upper buffer layer 120 near the interface between the upper buffer layer 120 and the electron transit layer 31 is Al_{0.01}Ga_{0.99}N. By achieving the composition gradient in the upper buffer layer 120, the band gap of the upper buffer layer 120 gradually narrows from a vicinity of the interface between the upper buffer layer 120 and the superlattice buffer layer 13 toward a vicinity of the interface between the upper buffer layer 120 and the electron transit layer 31. FIG. 11A illustrates a distribution of the Al composition ratio in the upper buffer layer 120 of the semiconductor device according to the present embodiment. FIG. 11B illustrates a distribution of a concentration of the impurity element in the upper buffer layer 120. In FIGS. 11A and 11B, 0 on the horizontal axis corresponds to the interface between the upper buffer layer 120 and the superlattice buffer layer 13.

In the present embodiment, if the upper buffer layer 120 is represented by Al_{z}Ga_{1-z}N, the upper buffer layer 120 is formed in a composition gradient manner so that the Al composition ratio gradually decreases from the side of the silicon substrate 10 toward the side of the electron transit layer 31 within a range of 0<z<1.0, more preferably, a range of 0<z≦0.5. Additionally, in the present embodiment, Fe as an impurity element is uniformly doped so that a concentration of Fe is about 5×10¹⁸ cm⁻³.

In a manufacturing process of the semiconductor device according to the present embodiment, when forming the upper buffer layer 120, a supply amount of TMA is gradually reduced as the growth of the upper buffer layer 120 progresses,

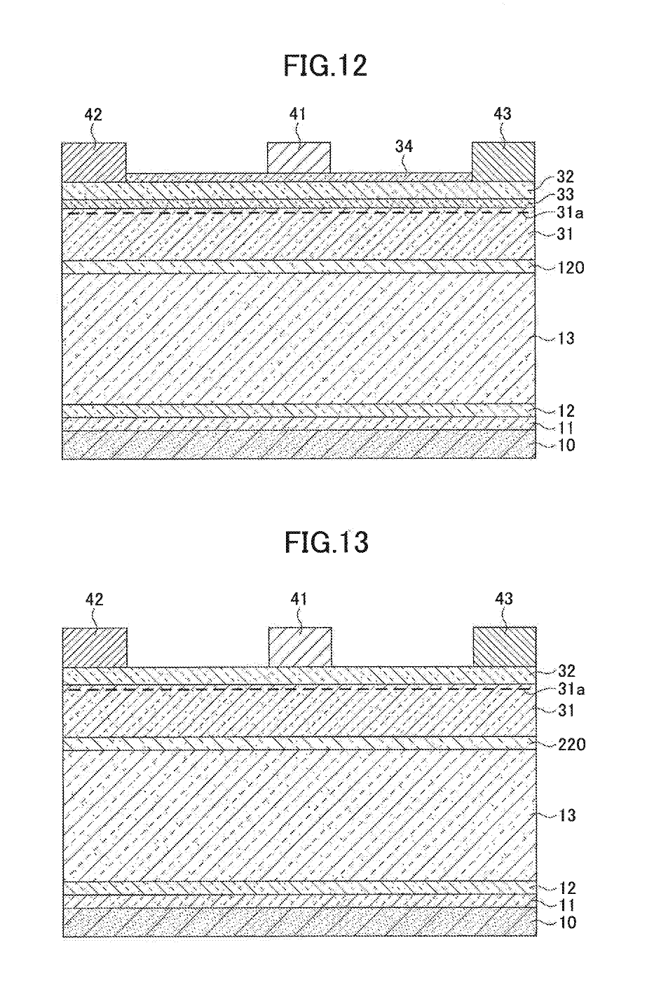

The semiconductor device according to the present embodiment may have a structure, as illustrated in FIG. 12, in which a spacer layer 33 is formed by i-GaN or the like between the electron transit layer 31 and the electron supply layer 32 and the cap layer 34 is formed by n-GaN or the like on the electron supply layer 32. In such a case, the gate electrode 41 is formed on the cap layer 34.

Configuration and arrangement of the semiconductor device according to the present embodiment other than the above-mentioned configuration and arrangement are the same as the configuration and arrangement of the semiconductor device according to the first embodiment.

### Third Embodiment

A description will be given below of a semiconductor device according to a third embodiment. As illustrated in FIG. 13, the semiconductor device according to the third embodiment includes a silicon substrate 10 and a nuclear formation layer 11, a lower buffer layer 12, a superlattice buffer layer 13, an upper buffer layer 220, an electron transit layer 31 and an electron supply layer 32 sequentially laminated on the silicon substrate 10 in that order. A gate electrode 41, a source electrode 42 and a drain electrode 43 are formed on the electron supply layer 32.

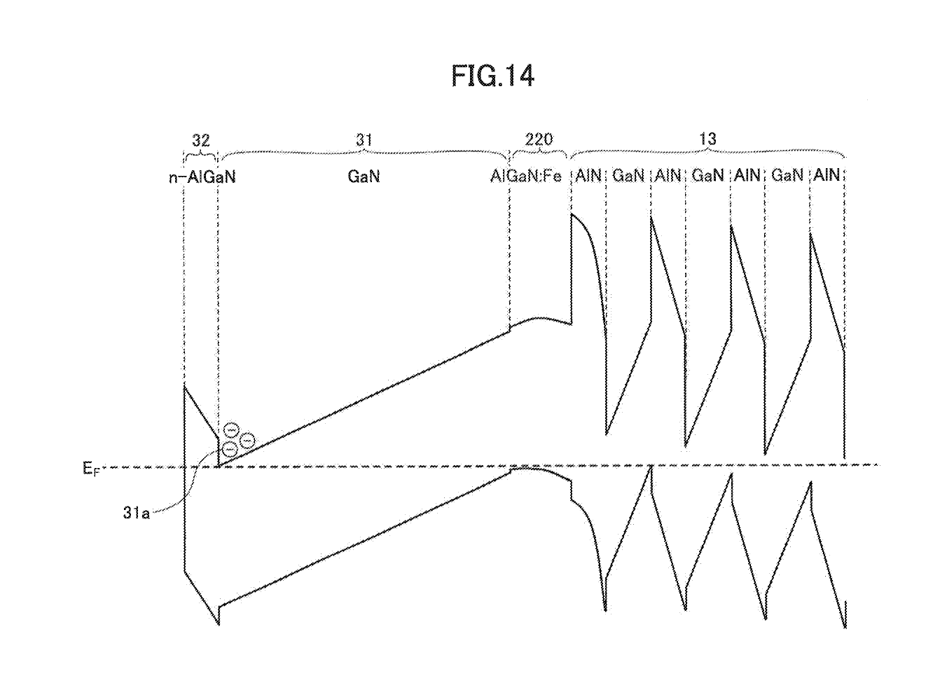

The nuclear formation layer 11 is formed by AlN. The lower buffer layer 12 is formed by AlGaN. The superlattice buffer layer 13 is formed by alternately lamina ting an AlN film and a GaN film for a predetermined number of cycles. The electron transit layer 31 is formed by i-GaN. The electron supply layer 32 is formed by n-AlGaN. Thereby, in the electron transit layer 31, a 2DEG 31a is created, near the interface between the electron transit layer 31 and the electron supply layer 32. FIG. 14 is an energy band diagram in the supper lattice buffer layer 13. the upper buffer layer 220, the electron transit layer 31 and the electron supply layer 32.

In the present embodiment, the upper buffer layer 220 is formed by Al_{0.2}Ga_{0.8}N doped with Fe as an impurity element. Thereby, generation of holes is suppressed in the vicinity of the interface between the superlattice buffer layer 13 and the upper buffer layer 220.

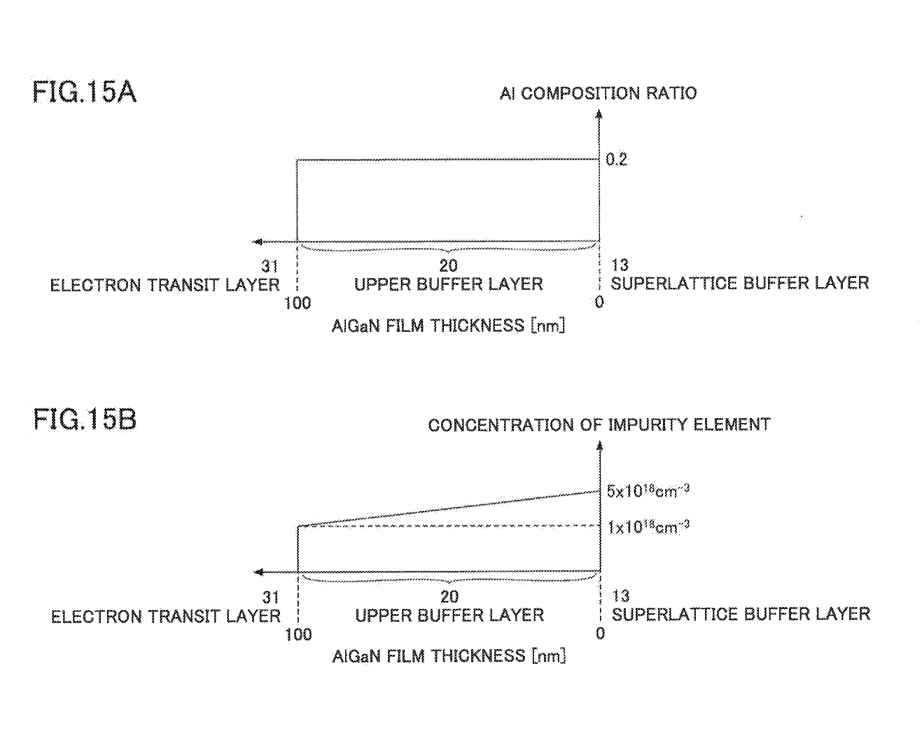

In the present embodiment, as illustrated in FIGS. 15A and 15B, the upper buffer layer 220 is formed so that a concentration of Fe gradually decreases from a vicinity of the interface between the upper buffer layer 220 and the superlattice buffer layer 13 toward a vicinity of the interface between the upper buffer layer 220 and the electron transit layer 31. Specifically, in the upper buffer layer 220, the concentration of Fe gradually decreases so that the concentration of Fe near the interface between the upper buffer layer 220 and the superlattice buffer layer 13 is 5×10¹⁸ cm⁻³ and the concentration of Fe near the interface between the upper buffer layer 220 and the electron transit layer 31 is 1×10¹⁸ cm⁻³. FIG. 15A illustrates a distribution of the Al composition ratio in the upper buffer layer 220 of the semiconductor device according to the present embodiment. FIG. 15B illustrates a distribution of a concentration of the impurity element in the upper buffer layer 220. In FIGS. 15A and 15B, 0 on the horizontal axis corresponds to the interface between the upper buffer layer 220 and the superlattice buffer layer 13.

In the present embodiment, the upper buffer layer 220 is formed so that a concentration of an impurity element such as Fe or the like decreases from the side of the silicon substrate 10 toward the side of the electron transit layer 31 within a range of greater than or equal to 1×10¹⁷ cm⁻³ and smaller than or equal to 1×10²⁰ cm⁻³. In the present embodiment, the upper buffer layer 220 is formed in a composition gradient manner so that an Al composition ratio gradually decreases from a vicinity of the interface between the upper buffer layer 220 and the superlattice buffer layer 13 toward a vicinity of the interface between the upper buffer layer 220 and the electron transit layer 31.

In a manufacturing process of the semiconductor device according to the present embodiment, when forming the upper buffer layer 220, a supply amount of Cp2Fe is gradually reduced as the growth of the upper buffer layer 220 progresses.

The semiconductor device according to the present embodiment may have a structure, as illustrated in FIG. 16, in which a spacer layer 33 is formed by i-GaN or the lake between the electron transit layer 31 and the electron supply layer 32 and the cap layer 34 is formed by n-GaN or the like on the electron supply layer 32. In such a case, the gate electrode 41 is formed on the cap layer 34.

Configuration and arrangement of the semiconductor device according to the present embodiment other than the above-mentioned configuration and arrangement are the same as the configuration and arrangement of the semiconductor device according to the first embodiment.

### Fourth Embodiment

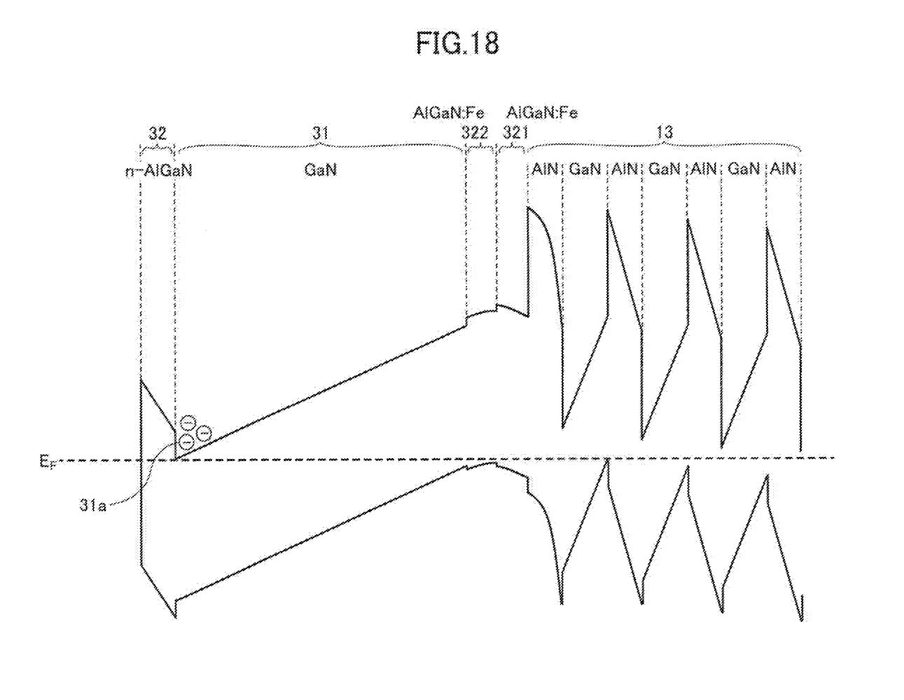

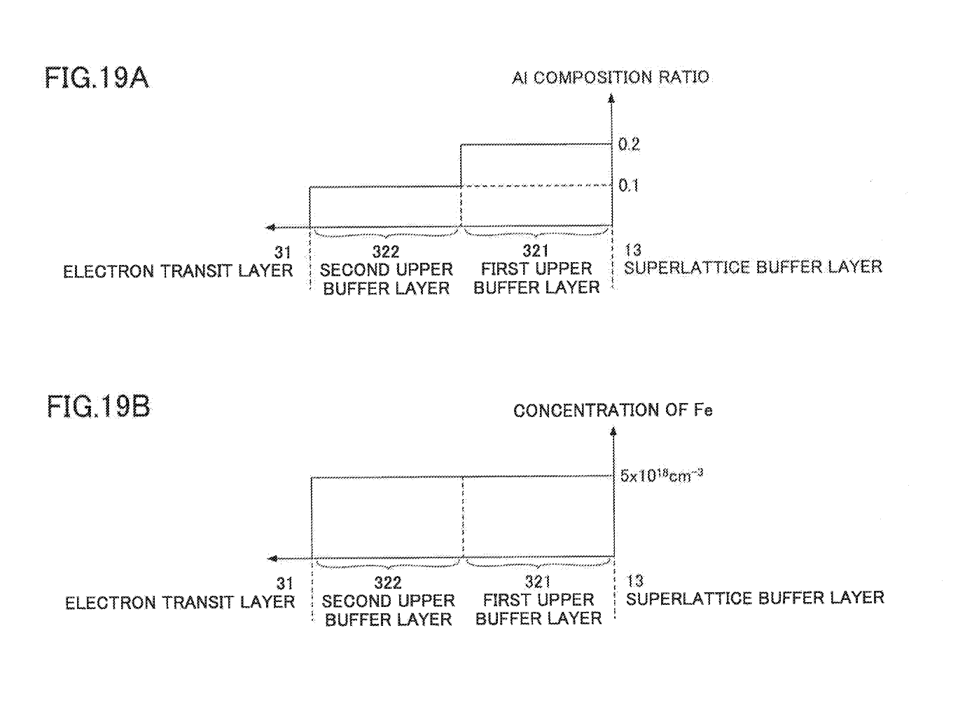

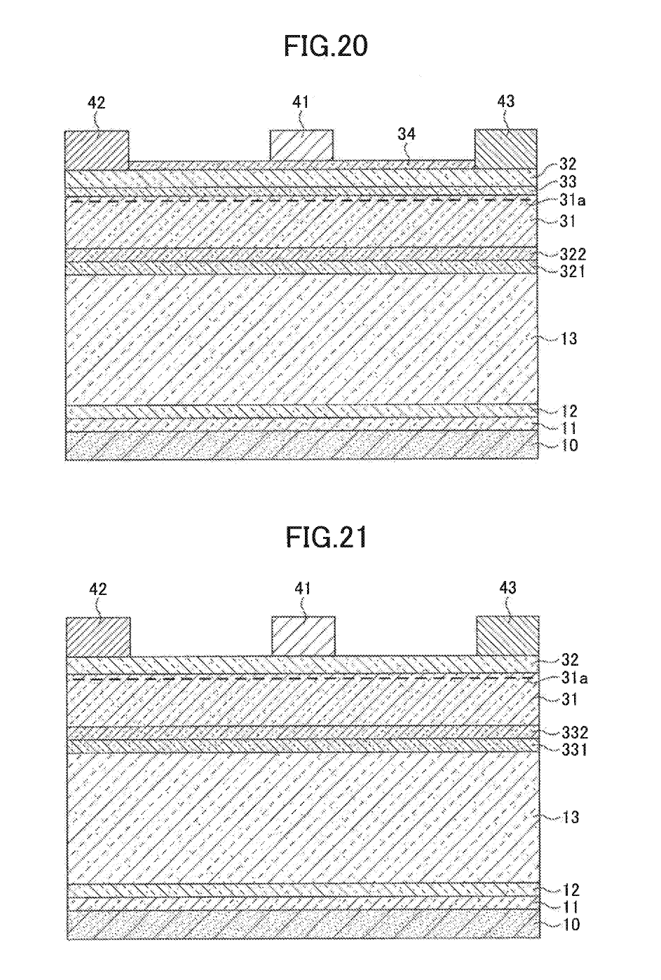

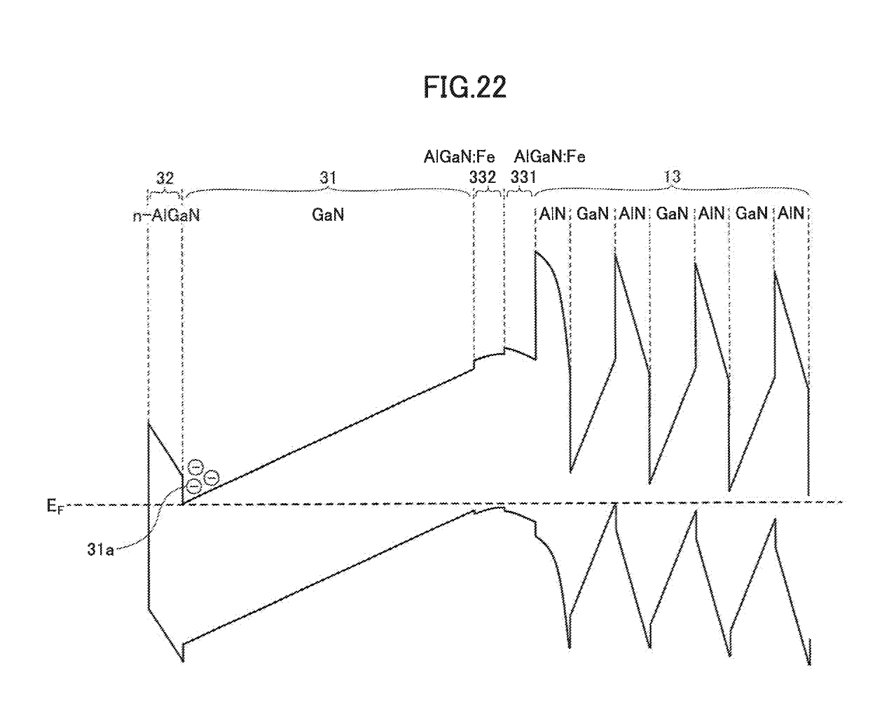

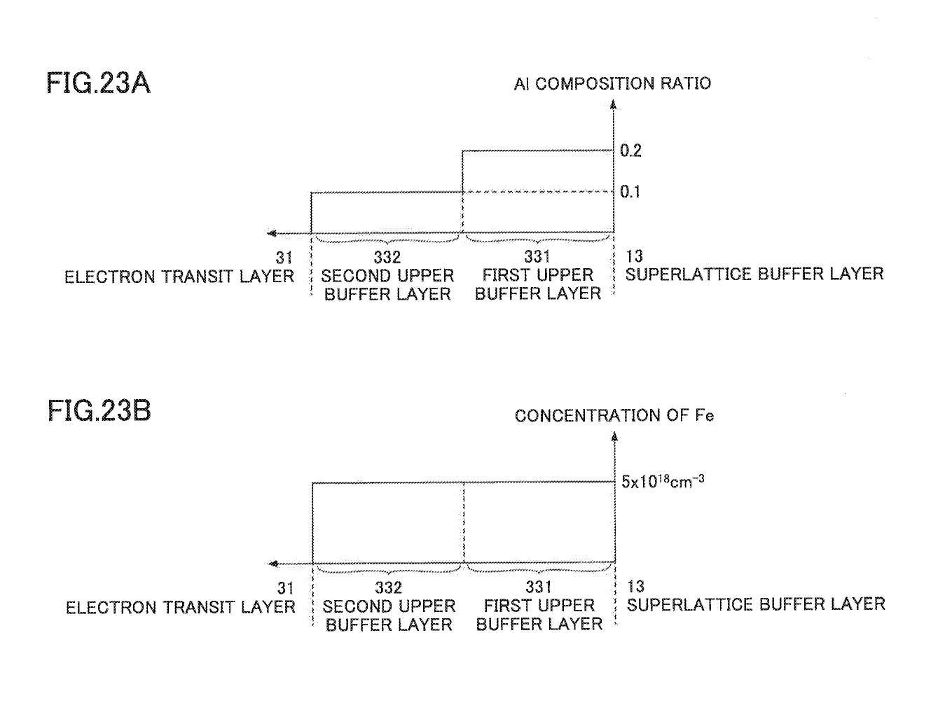

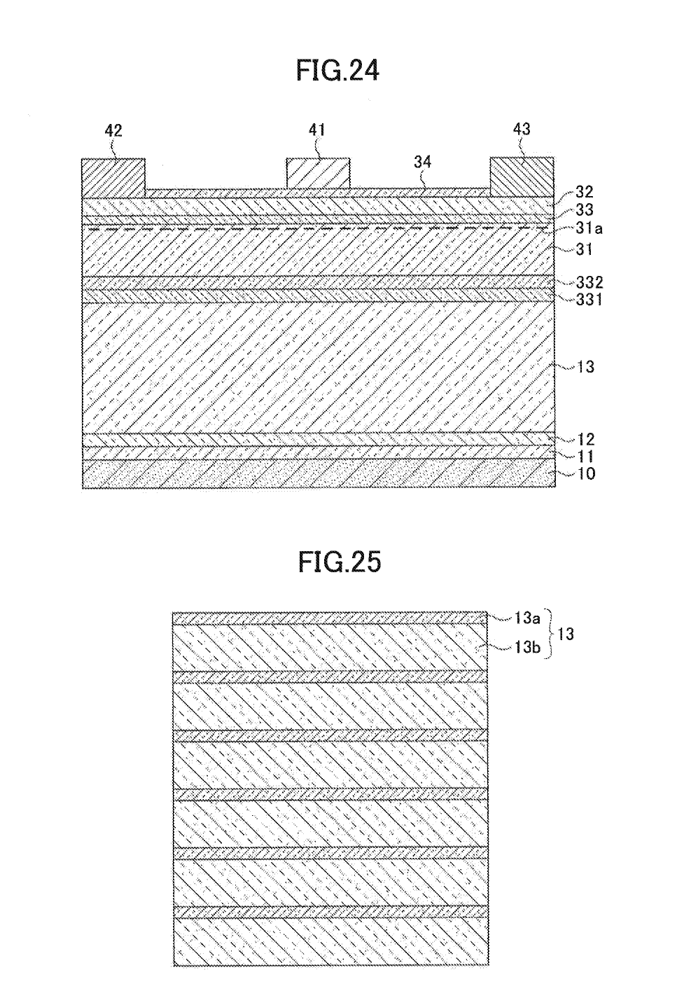

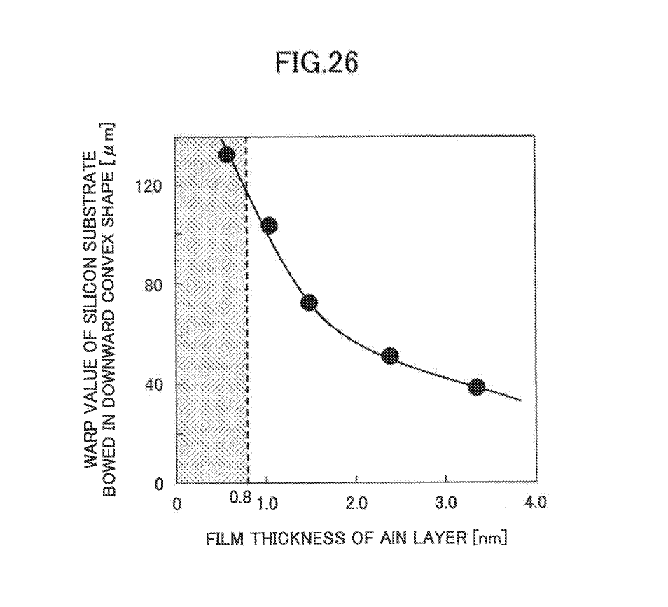

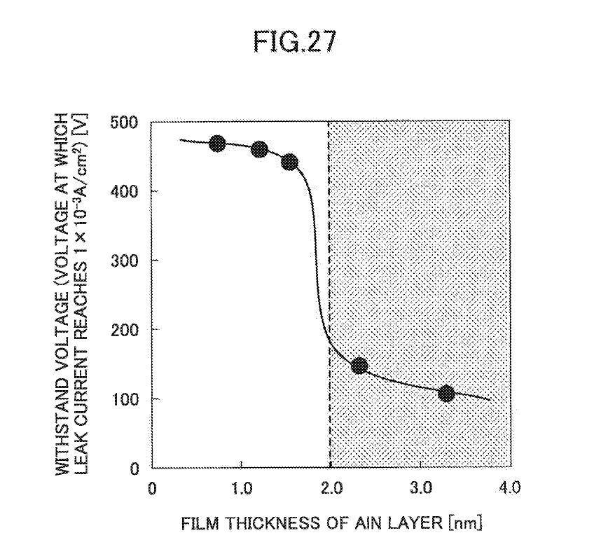

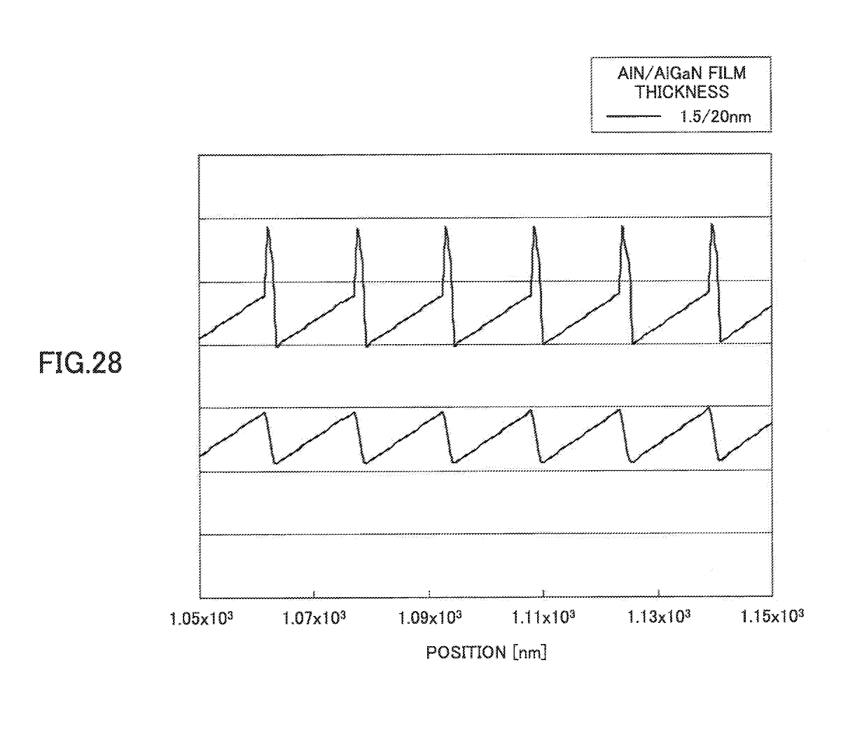

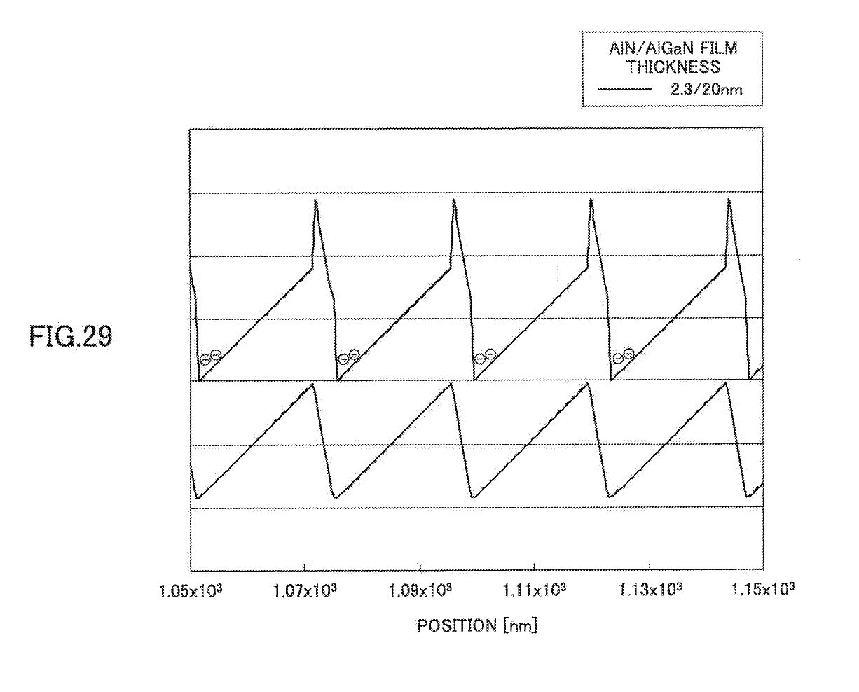

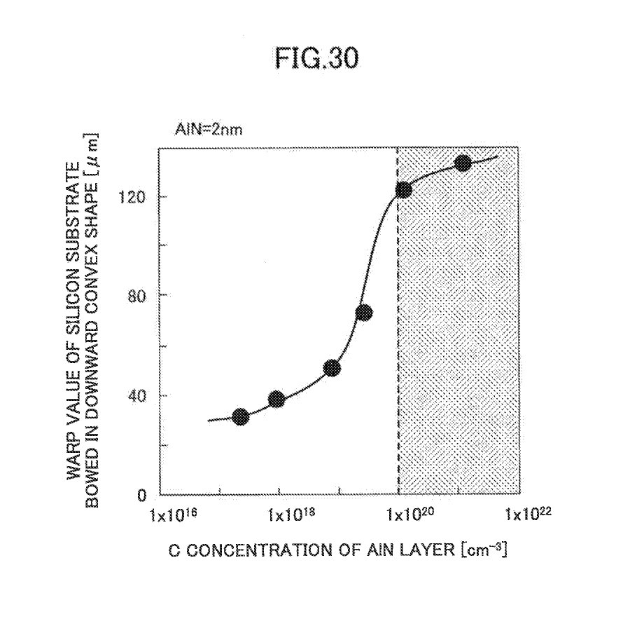

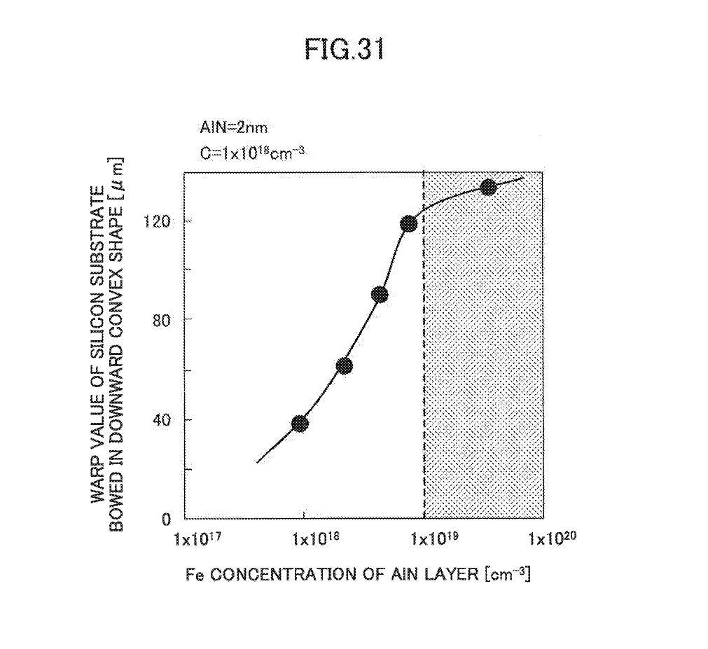

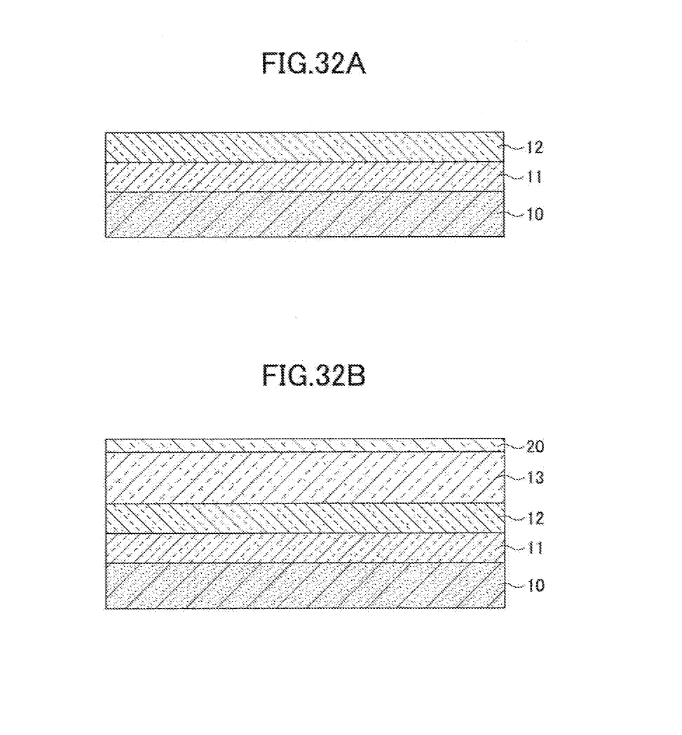

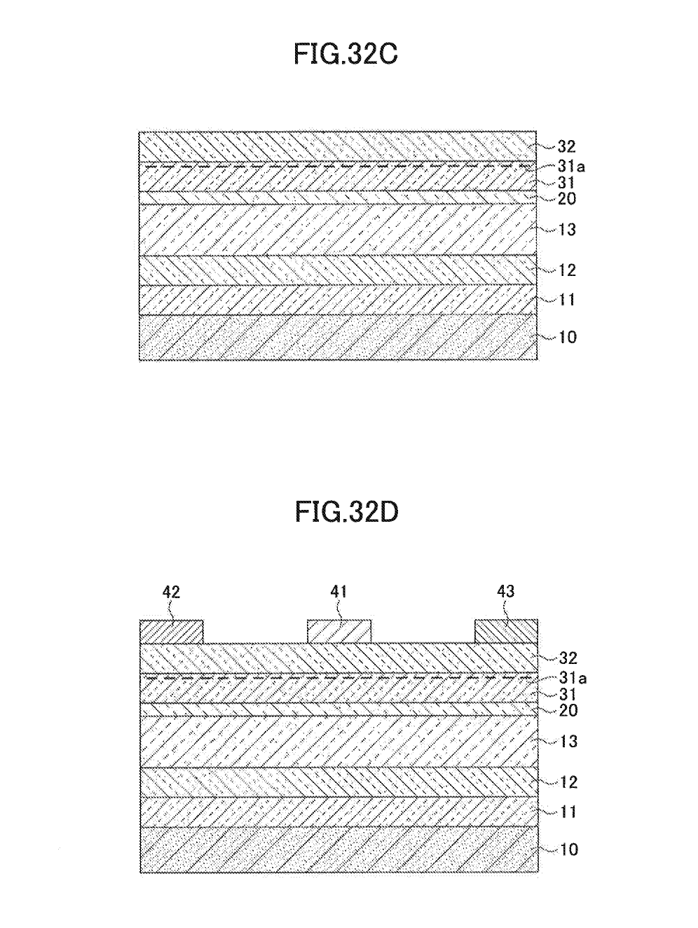

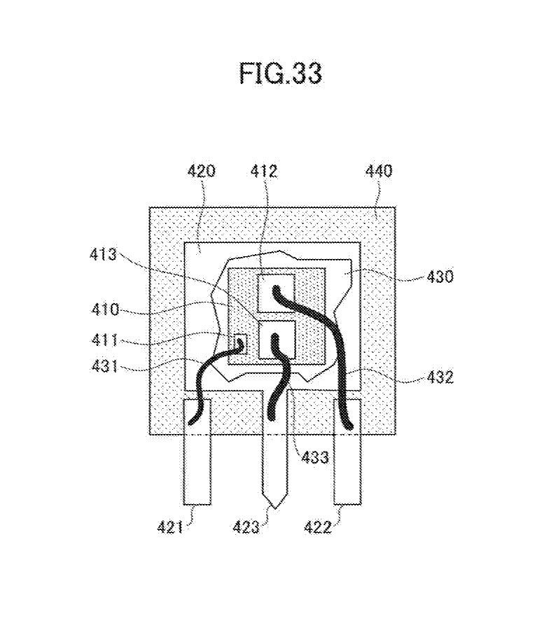

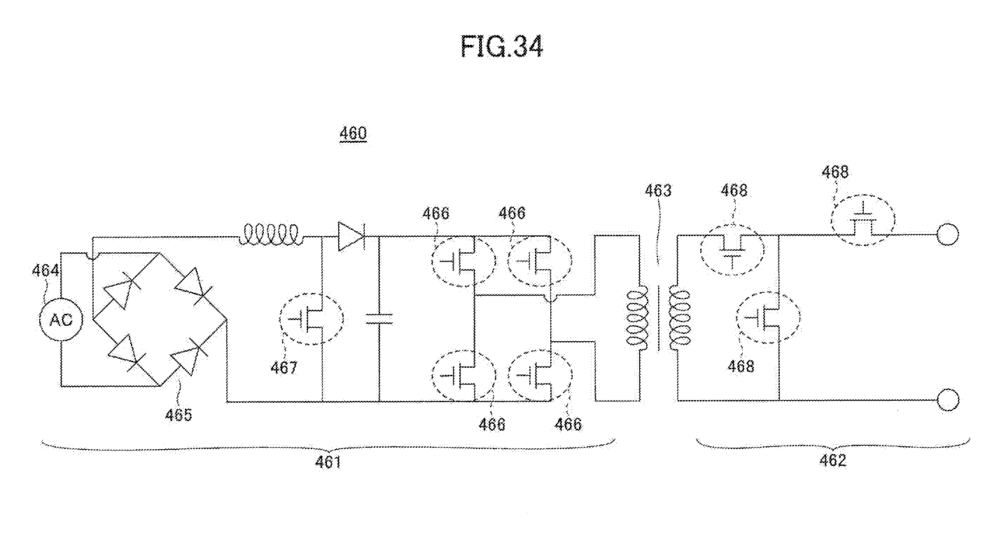

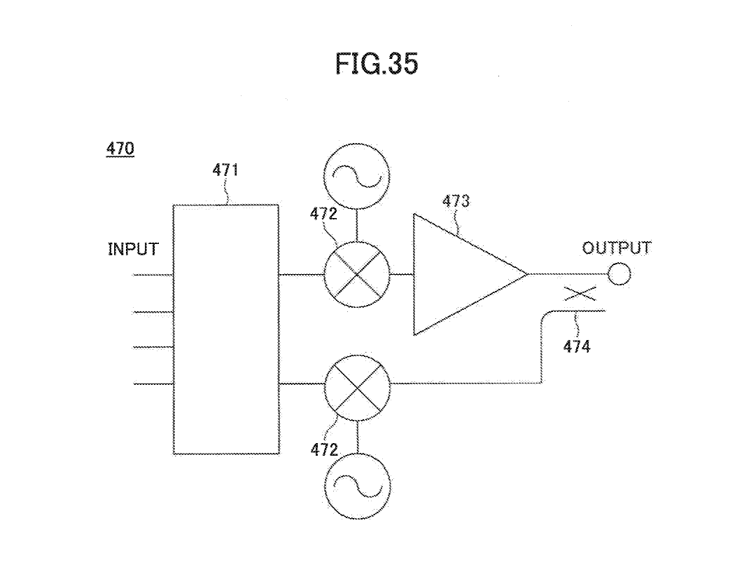

A description will be given below of a semiconductor device according to a fourth embodiment. As illustrated in FIG. 17, the semiconductor device according to the fourth embodiment includes an upper buffer layer composed of two AlGaN layers having different Al composition ratios. Specifically, the semiconductor device according to the present embodiment includes a silicon substrate 10 and a nuclear formation layer 11, a lower buffer layer 12, a superlattice buffer layer 13, a first upper buffer layer 321, a second upper buffer layer 322, an electron transit layer 31 and an electron supply layer 32 sequentially laminated on the silicon substrate 10 in that order. A gate electrode 41, a source electrode 42 and a drain electrode 43 are formed on the electron supply layer 32.

The nuclear formation layer 11 is formed by AlN. The lower buffer layer 12 is formed by AlGaN. The superlattice buffer layer 13 is formed by alternately laminating an AlN film and a GaN film for a predetermined cycles. The electron transit layer 31 is formed by i-GaN. The electron supply layer 32 is formed by n-AlGaN. Thereby, in the electron transit layer 31, a 2DEG 31a is created near the interface between the electron transit layer 31 and the electron supply layer 32. FIG. 18 is an energy band diagram in the supper lattice buffer layer 13, the first upper buffer layer 321, the second upper buffer layer 322, the electron transit layer 31 and the electron supply layer 32.

In the present embodiment, as illustrated in FIGS. 19A and 19B, the first upper buffer layer 321 is formed by Al_{0.2}Ga_{0.8}N doped with Fe as an impurity element at a concentration of about 5×10¹⁸ cm⁻³. The second upper Puffer layer 322 is formed by Al_{0.1}Ga_{0.9}N doped with Fe as an impurity element at a concentration of about 5×10¹⁸ cm⁻³. Thereby, generation of holes is suppressed in the vicinity of the interface between the superlattice buffer layer 13 and the first upper buffer layer 321.

FIG. 19A illustrates a distribution of an Al composition ratio in the first upper buffer layer 321 and the second upper buffer layer 322 in the semiconductor device according to the present embodiment. FIG. 19B illustrates a distribution of a concentration of an impurity element in the first upper buffer layer 321 and the second upper buffer layer 322.

In the present embodiment, if each of the first and second upper buffer layers 321 and 322 is represented by Al_{z}Ga_{1-z}N, each of the first and second upper buffer layers 321 and 322 is formed so that a value of z falls within a range of 0<z<1.0, more preferably within a range of 0z≦0.5. Additionally, the Al composition ratio of the first upper buffer layer 321 is higher than the Al composition ratio of the second upper buffer layer 322. Thereby, the band gap in the second upper buffer layer 322 is narrower than the band grip in the first upper buffer layer 321. Additionally, in the present embodiment, each of the first and second upper buffer layers 321 and 322 is formed so that a concentration of Fe as an impurity element fails within a range of greater than or equal to 1×10¹⁷ cm⁻³ and smaller than or equal to 1×10²⁰ cm⁻³.

In a manufacturing process of the semiconductor device according to the present embodiment, a supply amount of TMA when forming the second upper buffer layer 322 is reduced to be smaller than a supply amount of TMA when forming the first upper buffer layer 321.

The semiconductor device according to the present embodiment may have a structure, as illustrated in FIG. 20, in which a spacer layer 33 is formed by i-GaN or the like between the electron transit layer 31 and the electron supply layer 32 and the cap layer 34 is formed by n-GaN or the lake on the electron, supply layer 32. In snort a case, the gate electrode 41 is formed on the cap layer 34. Although the description has been given of the case where the upper buffer layer includes two AlGaN layers having different composition ratios, the upper buffer layer may be formed by three or more AlGaN films having different composition ratios.

Configuration and arrangement of the semiconductor device according to the present embodiment other than the above-mentioned configuration and arrangement are the same as the configuration and arrangement of she semiconductor device according to the first embodiment.

### Fifth Embodiment

A description will be given below of a semiconductor device according to a fifth embodiment. As illustrated in FIG. 21, the semiconductor device according to the fifth embodiment includes an upper buffer layer composed of two AlGaN layers having different Al composition ratios and different concentrations of an. impurity element such as Fe or the like. Specifically, the semiconductor device according to the present embodiment includes a silicon substrate 10 and a nuclear formation layer 11, a lower buffer layer 12, a superlattice buffer layer 13, a first upper buffer layer 331, a second upper buffer layer 332, an electron transit layer 31 and an electron supply layer 32 sequentially laminated on the silicon substrate 10 in that order. A gate electrode 41, a source electrode 42 and a drain electrode 43 are formed on the electron supply layer 32.

The nuclear formation layer 11 is formed by AlN. The lower buffer layer 12 is formed by AlGaN. The superlattice buffer layer 13 is formed by alternately laminating an AlN film and a GaN film for a predetermined number of cycles. The electron transit layer 31 is formed by i-GaN. The electron supply layer 32 is formed by n-AlGaN. Thereby, in the electron transit layer 31, a 2DEG 31a is created near the interface between the electron transit layer 31 and the electron supply layer 32. FIG. 22 is an energy band diagram in the supper lattice buffer layer 13, the first upper Puffer layer 331, the second upper buffer layer 332, the electron transit layer 31 and the electron supply layer 32.

In the present embodiment, as illustrated in FIGS. 23A and 23B, the first upper buffer layer 331 is formed by Al_{0.2}Ga_{0.8}N doped with Fe as an impurity element at a concentration of about 5×10¹⁸ cm⁻³. The second upper buffer layer 332 is formed by Al_{0.1}Ga_{0.9}N doped with Fe as an impurity element at a concentration of about 5×10¹⁸ cm⁻³. Thereby, generation of holes is suppressed in the vicinity of the interface between the superlattice buffer layer 13 and the first upper buffer layer 331.

FIG. 23A illustrates a distribution of an Al composition ratio in the first upper buffer layer 331 and the second upper buffer layer 332 in the semiconductor device according to the present embodiment. FIG. 23B illustrates a distribution of at concentration of an impurity element in the first upper buffer layer 331 and the second upper buffer layer 322.

In the present embodiment, if each of the first and second upper buffer layers 331 and 332 is represented by A_{z}Ga_{1-z}N, each of the first, and second upper buffer layers 331 and 332 is formed so that a value of z falls within a range of 0<z<1.0, more preferably within a range of O<z≦0.5. Additionally, the Al composition ratio of the first upper buffer layer 331 is higher than tire Al composition ratio of the second upper buffer layer 332. Additionally, in the present embodiment, each of the first and second upper buffer layers 331 and 332 is formed so that a concentration of Fe as an impurity element fails within a range of greater than or equal to 1×10¹⁷ cm⁻³ and smaller than or equal to 1×10²⁰ cm⁻³. A concentration or an impurity element such as Fe or the like in the first upper buffer layer 331 is higher than a concentration of an impurity element such as Fe or the like in the second upper buffer layer 332.

In a manufacturing process of the semiconductor device according to the present embodiment, a supply amount of TMA and a supply amount of Cp2Fe when forming the second upper buffer layer 332 is reduced to be smaller than a supply amount of TMA and a supply amount of Cp2Fe when forming the first upper buffer layer 321.

The semiconductor device according to the present embodiment may have a structure, as illustrated in FIG. 24, in which a spacer layer 33 is formed by i-GaN or the like between the electron transit layer 31 and the electron supply layer 32 and the cap layer 34 is formed by n-GaN or the like on the electron supply layer 32. In such a case, the gate electrode 41 is formed on the cap layer 34.

Although the description has been given of the case where the upper buffer layer includes two AlGaN layers having different composition ratios and different concentrations of an impurity element such as Fe or the like, the upper buffer layer may be formed by three or more AlGaN films having different composition ratios and different concentrations of an impurity element such as Fe or the like.

Configuration and arrangement of the semiconductor device according to the present embodiment other than the above-mentioned configuration and arrangement are the same as the configuration and arrangement of the semiconductor device according to the first embodiment.

### Sixth Embodiment

A description will be given below of a semiconductor device according to a sixth embodiment. In the above-mentioned semiconductor device, the leak current flowing in a vertical direction to the silicon substrate can be suppressed by thickening the superlattice buffer layer. However, if the superlattice buffer layer is thick, a warp of the silicon substrate becomes large. A description is given below of a result of consideration of a case where the superlattice buffer layer 13 is formed by alternately laminating the AlN layer 13a (first superlattice formation layer) and the AlGaN layer 13b (second superlattice formation layer) as illustrated in FIG. 25. Specifically, consideration is given of a case where the film thickness of the AlN layer 13a (first superlattice formation layer) is varied in the superlattice buffer layer 13.

FIG. 26 is a graph indicating a relationship between the film thickness of the AlN layer 13a (first superlattice formation layer) in the superlattice buffer layer 13 and a warp value of a deformation of the silicon substrate 10. As illustrated in FIG. 26, a warp in the silicon substrate can be reduced by increasing the film thickness of the AlN layer 13a (first superlattice formation layer) in the superlattice buffer layer 13. If the film thickness of the AlN layer 13a is smaller than 0.8 nm, the warp value of the silicon substrate 10 is greater than or equal to 120 μm, which is not preferable because a crack may be generated in the superlattice buffer layer 13 and the nitride semiconductor formed on the superlattice buffer layer 13. Thus, the film thickness of the AlN layer 13a (first superlattice formation layer) is preferably greater than or equal to 0.3 nm.

FIG. 27 is a graph indicating a relationship between the film thickness and the withstand voltage of the AlN layer 13a (first superlattice formation layer) in the superlattice buffer layer 13. In the present embodiment, the withstand voltage is defined as a voltage at which the leak current becomes 1×10⁻³ A/cm². As illustrated in FIG. 27, the withstand voltage is decreased by increasing the film thickness of the AlN layer 13a (first superlattice formation layer) in the superlattice buffer layer 13. Particularly, when the film thickness of the AlN layer 13a is around 2.0 nm, if the film thickness of the AlN layer 13a is increased, the withstand voltage is sharply decreased. When the thickness of the AlN layer 13a exceeds 2.0 nm, the withstand voltage becomes smaller than 200 V, which is not preferable. Thus, it is preferable that the film thickness of the AlN layer 13a (first superlattice formation layer) is smaller than or equal to 2.0 nm.

A description will be given below, with reference to FIGS. 28 and 29, of a change in the withstand voltage caused by a change in the film thickness of the AlN layer 13a in the superlattice buffer layer 13. FIG. 28 is an energy band diagram of the superlattice buffer layer 13, which is formed by alternately laminating the AlN layer 13a having the film thickness of 1.5 nm and the AlGaN layer 13b having the film thickness of 20 nm. FIG. 29 is an energy band diagram of the superlattice buffer layer 13, which is formed by alternately laminating the AlN layer 13a having the film thickness of 2.3 nm and the AlGaN layer 13b having the film thickness of 20 nm. The lower ends of conducting bands in the graph of FIG. 29 are positioned lower than the lower ends of conducting bands in the graph of FIG. 28. Because electrons tend to be pooled at the lower ends of conducting bands, the superlattice buffer layer 13 of FIG. 29 has a withstand voltage lower than the superlattice buffer layer 13 of FIG. 28.

As mentioned above, when the film thickness of the AlN layer 13a is varied, a warp of the silicon substrate 10 and a withstand voltage are in a trade-off relation. Based on the relationship between a warp of the silicon substrate 10 and the withstand voltage, it is preferable that the film thickness of the AlN layer 13a (first superlattice formation layer) in the superlattice buffer layer 13 is greater than or equal to 0.8 nm and smaller than or equal to 2.0 nm.

A description will be given, with reference to FIG. 30, of a relationship between a concentration of an impurity element C doped into the AlN layer 13a and a warp of the silicon substrate 10. FIG. 30 is a graph indicating a relationship between the concentration of the impurity element C doped into the AlN layer 13a (first superlattice formation layer) and a warp value of a deformation of the silicon substrate 10 in the superlattice buffer layer 13. The film thickness of the AlN layer 13a is 2 nm.

As illustrated in FIG. 30, a warp in the silicon substrate 10 becomes large when the concentration of C in the AlN layer 13a (first superlattice formation layer) in the superlattice buffer layer 13 is increased. If the concentration of C in the AlN layer 13a exceeds 1×10²⁰ cm⁻³, the warp value of the warp of the silicon substrate 10 becomes greater than, or equal to 120 μm, which is not preferable because a crack may be generated in the film. Thus, the concentration of C, which is an impurity element doped into the AlN layer 13a (first superlattice formation layer) in the superlattice buffer layer 20, is preferably smaller than or equal to 1×10²⁰ cm⁻³. It should be noted that a desired withstand voltage cannot be obtained unless certain amount of C is doped into the AlN layer 13a. Thus, it is preferable that the concentration of C, which is an impurity element doped into the AlN layer 13a (first superlattice formation layer) in the superlattice buffer layer 13, is greater than or equal to 1×10¹⁷ cm⁻³.

As mentioned above, based on the relationship between a warp of the silicon substrate 10 and a withstand voltage, it is preferable that the concentration of C, which is an impurity element doped into the AlN layer 13a (first superlattice formation layer) in the superlattice buffer layer 13, is greater than or equal to 1×10¹⁷ cm⁻³ and smaller than or equal to 1×10²⁰ cm⁻³.

A description will be given below, with reference to FIG. 31, of a relationship between a concentration of an impurity element Fe doped into the AlN layer 13a and a warp of the silicon substrate 10. FIG. 31 is a graph indicating a relationship between a concentration of an impurity element Fe doped into the AlN layer 13a (first superlattice formation layer) in the superlattice buffer layer 13 and a warp value of a deformation of the silicon substrate 10. The film thickness of the AlN layer 13a (the first superlattice formation layer) is 2 nm. C as an impurity element is doped into the AlN layer 13a at a concentration of 1×10¹⁸ cm⁻³.

As illustrated in FIG. 31, a warp in the silicon substrate 10 becomes large when the concentration of Fe in the AlN layer 13a (first superlattice formation layer) in the superlattice buffer layer 13 is increased. If the concentration of Fe in the AlN layer 13a exceeds 1×10²⁰ cm⁻³, the warp value of the warp of the silicon substrate 10 becomes greater than or equal to 120 μm, which is not preferable because a crack tray be generated in the film. Thus, the concentration of Fe, which is an impurity element doped into the AlN layer 13a (first superlattice formation layer) in the superlattice buffer layer 13, is preferably smaller than or equal to 1×10¹⁹ cm⁻³.

Thus, in the present embodiment, in the case where the film thickness of the AlN layer 13a in the superlattice buffer layer 13 is greater than or equal to 0.8 nm and smaller than or equal to 2.0 nm, if the impurity element doped into the AlN layer 13a is C, the concentration of C is greater than or equal to 1×10^{∫}cm⁻³ and smaller than or equal to 1×10²⁰ cm⁻³. Moreover, in the case where the film thickness of the AlN layer 13a in the superlattice buffer layer 13 is greater than or equal to 0.8 nm and smaller than or equal to 2.0 nm, if the impurity element doped into the AlN layer 13a is Fe, the concentration of Fe is smaller than or equal to 1×10¹⁹ cm⁻³. The semiconductor device according to the present embodiment includes the superlattice buffer layer 13 having the above-mentioned AlN layer 13a.

In the present embodiment, the first superlattice formation layer serving as the AlN layer 13a may be formed by AlₓGa₁₋ₓN, and the value of x may be greater than or equal to 0.5 and smaller than or equal to 1. The second superlattice formation layer serving as the AlGaN layer 13b may be formed by Al_{y}Ga_{1-y}N, and the value of y may be greater than 0 and smaller than 0.5. Accordingly, a relationship x>y is satisfied in true superlattice buffer layer 13. More preferably, the first superlattice formation layer is formed by AlN. As the impurity element serving as an acceptor doped into the superlattice buffer layer 13b, Mg, Zn, Be, Cd, Li, etc., other than C and Fe may be used.

(Manufacturing Method of Semiconductor Device)

A description will now be given, with reference to FIGS. 32A through 32D, of a manufacturing method of the semiconductor device according to the present embodiment. According to the manufacturing method of the semiconductor device of the present embodiment, the nitride semiconductor layer is formed on the silicon substrate 10 by epitaxial growth using a metal organic chemical vapor deposition (MOCVD) or a molecular beam epitaxy (MBE). In the following explanation, it is assumed that the nitride semiconductor layer is formed by MOCVD. When forming the nitride semiconductor layer, trimethyl aluminum (TMA) is used as an Al source gas, trimethyl gallium (TMG) is used as a Ga source gas, and ammonium (NH₃) is used as a N source gas.

First, as illustrated in FIG. 32A, a nuclear formation layer 11 and a buffer layer 12 are formed by a nitride semiconductor sequentially on the silicon substrate 10. Although a silicon (111) substrate is used as the silicon substrate 10 in the present embodiment, a substrate formed of SiC, sapphire, GaN, etc., may be used instead of the silicon substrate 10. The nuclear formation layer 11 is formed of an AlN film having a thickness of 200 nm. The lower buffer layer 12 is formed by Al_{0.4}Ga_{0.6}N.

The nuclear formation layer 11 is formed by causing growth in a condition in which a substrate temperature is about 1000° C., a V/III ratio is 1000 to 2000, and a pressure in a chamber of an MOCVD apparatus is about 5 kPa. The lower buffer layer 12 is formed by causing growth in a condition in which a substrate temperature is about 1000° C., a V/III ratio is 100 to 300, and a pressure in a chamber of an MOCVD apparatus is about 3 kPa. In the present embodiment, it is preferable to cause a growth of the nuclear formation layer 11 under a condition with which an amount of C taken into the film is small. As for the lower buffer layer 12, in order to achieve flatness, it is preferable to cause a growth in a condition in which the V/III ratio is decreased.

Then, as illustrated in FIG. 32B, the superlattice layer 13 and the upper buffer layer 20 are formed on the lower buffer layer 12. Specifically, as illustrated in FIG. 25, the superlattice buffer layer 13 is formed by alternately and cyclically laminating the AlN layer 13a and the AlGaN layer 13b. The thus-formed AlN layer 13a has a film thickness of about 1.5 nm. The AlGaN layer 13b has a film thickness of about 20 nm. It is preferable to make a thickness of the AlN layer 13a to be smaller than or equal to 2 nm. Additionally, the thickness of the AlN layer 13a is preferably greater than or equal to 0.8 nm in order to reduce a warp of the silicon substrate 10. The AlGaN layer 13b is formed by Al_{0.2}Ga_{0.3}N. A temperature of the substrate when forming the superlattice buffer layer 20 is about 1020° C. The superlattice buffer layer 20 is formed by causing a growth in a condition in which a pressure in the chamber of the MOCVD apparatus is about 5 kPa.

According to the present embodiment, C is used as an impurity element serving as an acceptor doped into the AlN layer 13a. A miring amount of C is adjusted by changing a V/III ratio. Specifically, in order to set the concentration of G in the AlN layer 13a, the AlN layer 13a is caused to grow in a condition in which the V/III ratio is about 600. It should be noted that the impurity concentration in the AlN layer 13a is preferably greater than or equal to 1×10^{∫}cm⁻³ and smaller than or equal to 1×10²⁰ cm⁻³.

Then, as illustrated in FIG. 32C, the electron transit layer 31 and the electron supply layer 32 are laminated on the upper buffer layer 20. More specifically, the electron transit layer 31 is formed by causing a GaN film having a thickness of about 1 μm to grow on the upper buffer layer 20 under a condition in which a growth temperature is about 1000° C. and a pressure in the chamber of the MOCVD apparatus is about 100 to 300 mbar (10 to 30 kPa). The electron supply layer 32 is formed by causing an AlGaN film having a thickness of about 20 nm to grow on the electron transit layer 31 under a condition in which a growth temperature is about 1000° C. and a pressure in the chamber of the MOCVD apparatus is about 100 to 200 mbar (10 to 20 kPa). In the present embodiment, the electron supply layer 32 is formed by Al_{0.2}Ga_{0.9}N.

Then, as illustrated in FIG. 32D, the source electrode 42 and the drain electrode 43 are formed on the electron supply layer 32 and further the gate electrode 41 is formed on the electron supply layer 32. Specifically, a photoresist is applied on the electron supply layer 32, and an exposure and development is performed by at exposure apparatus so as to form a resist pattern (not illustrated in the figure) having openings in areas where the source electrode 12 and the drain electrode 43 are to be formed. Thereafter, a metal lamination film made of a Ti/Al film is formed by a vacuum deposition. Then, the metal lamination film formed on the resist pattern is removed together with the resist pattern by immersing the resist pattern into an organic solvent or the like. Thereby, the source electrode 42 and the drain electrode 43 are formed by remaining portions of the metal lamination film. Thereafter, a rapid thermal anneal (RTA) is performed to cause the source electrode 42 and the drain electrode 43 to make an ohmic contact with each other. It should be noted that in the metal lamination film made of Ti/Al film, the film thickness of the Ti film is about 100 nm and the film thickness of the Al film is about 300 nm.

Thereafter, a photoresist is applied on the electron supply layer 32 again, and an exposure and development is performed by an exposure apparatus so as to form a resist pattern (not illustrated in the figure) having an opening in an area where the gate electrode 41 is to be formed. Thereafter, a metal lamination film made of a Ni/Au film is formed by a vacuum deposition. Then, the metal lamination film formed on the resist pattern is removed together with the resist pattern by immersing the resist pattern, into an organic solvent or the like. Thereby, the gate 41 is formed by a remaining portion of the metal lamination film. It should be noted that in the metal lamination film made of Ni/Au film, the film thickness of the Ni film is about 50 nm and the film, thickness of the An film is about 300 nm.

The semiconductor device according to the present embodiment can be manufactured by the above-mentioned processes.

It should be noted that, in the present embodiment, when forming the AlN layer 13a in the superlattice buffer layer 13, Fe may be doped as an impurity element serving as an acceptor. In such a case, the concentration of Fe doped is preferably smaller than or equal to 1×10¹⁹ cm⁻³. For Example, the concentration of Fe is preferably 1×10¹⁸ cm⁻³. As a source gas when doping Fe, for example, ferrocene (Cp2Fe) is used. Manufacturing processes other than the above-mentioned processes are the same as the manufacturing processes of the semiconductor device according to the first embodiment.

### Seventh Embodiment

A description writ be given below of a semiconductor device, power supply device and high-frequency amplifier according to a seventh embodiment.

The semiconductor device according to the seventh embodiment includes one of the semiconductor devices according to the first through sixth embodiments that is incorporated into a discrete package. The discrete-packaged semiconductor device is described with reference to FIG. 33. FIG. 33 schematically illustrates an interior of the discrete-packaged semiconductor device. The configuration and arrangement of the electrodes of the semiconductor device incorporated in the discrete package are different from those of the semiconductor devices according to the first through sixth embodiments.

First, an HEMT semiconductor chip 410 of GaN semiconductor material is formed by one of the semiconductor devices according to the first through sixth embodiments. Then, the semiconductor chip 410 is fixed on a lead frame 420 by a die-attachment agent 430 such as solder or the like. The semiconductor chip 410 corresponds to one of the semiconductor device according to the first through sixth embodiments.

Then, a gate electrode 411 is connected to a gate lead 421 by a bonding wire 431, a source electrode 412 is connected to a source lead 422 by a bonding wire 432 and a drain electrode 413 is connected to a drain lead 423 by a bonding wire 433. The bonding wires 431, 432 and 433 are made of a metal material such as Al or the like. In the present embodiment, the gate electrode 411 is a gate electrode pad, which is connected to the gun electrode 41 of one of the semiconductor devices according to the first through fourth embodiments. The source electrode 412 is a source electrode pad, which is connected to the source electrode 42 of one of the semiconductor devices according to the first through sixth embodiments. The drain electrode 413 is a drain electrode pad, which is connected to the drain electrode 43 of one of the semiconductor devices according to the first through sixth embodiments.

Then, the semiconductor chip 410 and the lead frame 420 are encapsulated by a mold resin 440 using a transfer mold method. As mentioned, above, the discrete-packaged semiconductor device, which is an HEMT using GaN semiconductor material, is fabricated.

A description is given of a power supply device and a high-frequency amplifier according to the seventh embodiment. The power supply device and the high-frequency amplifier according to the seventh embodiment incorporate therein one of the semiconductor devices according to the first through sixth embodiments.

First, a description is given, with reference to FIG. 34, of a power supply device according to the seventh embodiment. The power supply device 460 according to the seventh embodiment includes a primary circuit 461 of a high-voltage, a secondary circuit 461 of a low-voltage, and a transformer 463 provided, between the primary circuit 461 and the secondary circuit 462. The primary circuit 461 includes an alternating-voltage power source 464, a so-called bridge rectifying circuit 465, a plurality of switching devices 466 (four switching devices are illustrated in FIG. 34) and another switching device 467. The secondary circuit 462 includes a plurality of switching devices 468 (three switching devices are illustrated in FIG. 34). In the power supply device 460 illustrated in FIG. 34 semiconductor devices according to the first through fourth embodiments are used as the switching devices 466 and 467 of the primary circuit 461. The switching devices 466 and 467 of the primary circuit 461 are preferably normally-off semiconductor devices. A metal insulator semiconductor filed effect transistor (MISFFT) is used as the switching device 468 of the secondary circuit 462.

A description is given below, with reference to FIG. 35, of a high-frequency amplifier according to the seventh embodiment. The high-frequency amplifier 470 according to the present embodiment may be applied to, for example, a power amplifier of a base station of a cellular phone system. The high-frequency amplifier 470 includes a digital predistortion circuit 471, a mixer 472, a power amplifier 473 and a directional coupler 474. The digital predistortion circuit 471 compensates for a linear distortion of an input signal. The mixer 472 mixes the input signal of which a linear distortion is compensated and an alternating current signal. The power amplifier 473 amplifies the input signal mixed with the alternating current signal. In the circuit illustrated in FIG. 29, the power amplifier 473 includes one of the semiconductor devices according to the first through fourth embodiments. The directional coupler 474 monitors the input signal and an output signal. In the circuit illustrated in FIG. 35, for example, an output signal can be mixed with the alternating current signal by the mixer 472 and can be sent to the digital predistortion circuit 471.

All examples and conditional language recited herein are intended for pedagogical purposes to aid the reader in understanding the principles of the invention and the concepts contributed by the inventor to furthering the art, and are to be construed a being without limitation to such specifically recited examples and conditions, nor does the organization of such examples in the specification relates to a showing of the superiority and inferiority of the invention. Although the embodiment(s) of the present invention(s) has(have) been described in detail, it should be understood that the various changes, substitutions, and alterations could be made hereto without departing from the spirit and scope of the invention.

What is claimed is:

1. A semiconductor device comprising:
a superlattice buffer layer formed on a substrate;
an upper buffer layer formed on said superlattice buffer layer;
a first semiconductor layer formed by a nitride semiconductor on said upper buffer layer;
a second semiconductor layer formed by a nitride semiconductor on said first semiconductor layer; and
a gate electrode, a source electrode and a drain electrode formed on said second semiconductor layer,
wherein said superlattice buffer layer is formed by cyclically laminating nitride semiconductor films having different compositions, and
said upper buffer layer is formed by a nitride semiconductor material having a band gap wider than a band gap of said first semiconductor layer and doped with an impurity element that causes a depth of an acceptor level to be greater than or equal to 0.5 eV.

2. The semiconductor device as claimed in claim 1, wherein a concentration of said impurity element of said upper buffer layer decreases from a side of said substrate toward a side of said first semiconductor layer.

3. The semiconductor device as claimed in claim 1, wherein a band gap of said upper buffer layer narrows from a side of said substrate toward a side of said first semiconductor layer.

4. The semiconductor device as claimed in claim 1, wherein said upper buffer layer includes a first upper buffer layer and a second upper buffer layer, said first upper buffer layer being formed on a side of said substrate and second ripper layer being formed on said first semiconductor side, a band gap of said second upper buffer layer is narrower than a bad gap of said first buffer layer.

5. The semiconductor device as claimed in claim 1, wherein said upper buffer layer includes a first upper buffer layer and a second upper buffer layer, said first upper buffer layer being formed on a side of said substrate and second upper layer being formed on said first semiconductor side, a concentration of said impurity element of said second upper buffer layer is lower than a concentration of said impurity element of said first buffer layer.

6. The semiconductor device as claimed in claim 1, wherein said upper buffer layer is formed by one of GaN, AlN and InN or a mixed crystal containing two or more of GaN, AlN and InN.

7. The semiconductor device as claimed in claim 1, wherein said upper buffer layer is formed by a material co retaining AlGaN.

8. The semiconductor device as a claimed in claim 3, wherein said upper buffer layer is formed by a material containing AlGaN, and an Al composition ratio of said upper buffer layer decreases from said side of said substrate toward said side of said first semiconductor layer.

9. The semiconductor device as claimed in claim 4, wherein each of said upper buffer layer and said second upper buffer layer is formed by a material containing AlGaN, and an Al composition ratio of said second upper buffer layer is lower than an Al composition ratio of said first upper buffer layer.

10. The semiconductor device as claimed in claim 1, wherein a concentration of said impurity element in said upper buffer layer is higher than or equal to 1×10¹⁷ cm⁻³ and lower than or equal to 1×10²⁰ cm⁻³.

11. The semiconductor device as claimed in claim 1, wherein said superlattice buffer layer is formed by alternately laminating a film containing AlN and a film containing GaN for a predetermined number of cycles.

12. The semiconductor device as claimed in claim 1, wherein said superlattice buffer layer is formed by alternately laminating a film containing AlN and a film containing AlGaN for a predetermined number of cycles.

13. The semiconductor device as claimed in claim 1, wherein said first semiconductor layer is formed by a material containing GaN.

14. The semiconductor device as claimed in claim 1, wherein said second semiconductor layer if formed by a material containing AlGaN.

15. The semiconductor device as claimed in claim 1, further comprising a third semiconductor layer between said first semiconductor layer and said second semiconductor layer, the third semiconductor layer being formed by a nitride semiconductor.

16. The semiconductor device as claimed in claim 15 wherein said third semiconductor layer is formed by a material containing AlGaN.

17. The semiconductor device as claimed in claim 1, further comprising a fourth semiconductor layer on said second semiconductor layer, said fourth semiconductor layer being formed by an n-type nitride semiconductor.

18. The semiconductor device as claimed in claim 17, wherein said fourth semiconductor layer is formed by GaN doped with an n-type impurity element.

19. The semiconductor device as claimed in claim 1, further comprising a lower buffer layer between said substrate and said superlattice buffer layer.

20. A manufacturing method of a semiconductor device, comprising:
forming a superlattice buffer layer on a substrate;
forming an upper buffer layer on said superlattice buffer layer;
forming a first semiconductor layer by a nitride semiconductor on said upper buffer layer;
forming a second semiconductor layer by a nitride semiconductor on said first semiconductor layer; and
forming a gate electrode, a source electrode and a drain electrode on said second semiconductor layer,
wherein said superlattice buffer layer is formed by alternately and cyclically laminating nitride semiconductor films having different compositions, and said upper buffer layer is formed by a nitride semiconductor material having a band gap wider than a band gap of said first semiconductor layer and doped with an impurity element that causes a depth of an acceptor level to be greater than or equal to 0.5 eV.
